(19) United States
(12) Patent Application Publication
(10) Pub. No.: US 2010/0261058 A1
(43) Pub. Date: Oct. 14, 2010

(54) COMPOSITE MATERIALS CONTAINING METALLIZED CARBON NANOTUBES AND NANOFIBERS

(75) Inventors: SERGEY D. LOPATIN, Morgan Hill, CA (US); Robert Z. Bachrach, Burlingame, CA (US); Liang-Yuh Chen, San Jose, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/759,387

(22) Filed: Apr. 13, 2010

Related U.S. Application Data
(60) Provisional application No. 61/168,886, filed on Apr. 13, 2009.
(60) Provisional application No. 61/180,607, filed on May 22, 2009.

(51) Int. Cl. H01M 4/583; H01M 4/36; H01M 4/60; B05D 5/12; B05C 13/00; B05C 9/14; C23C 16/22; C23C 16/458

(52) U.S. Cl. 429/212; 429/231.8; 429/220; 429/223; 427/126.1; 427/122; 118/500; 118/58; 118/728; 977/700; 977/742; 977/948

(57) ABSTRACT

A method and apparatus are provided for the cost effective formation of a composite material which includes metallized carbon nanotubes and/or nanofibers that can be used to form portions of an energy storage device, such as a lithium ion battery. In one embodiment, carbon nanotubes are formed on a host substrate using a catalytic chemical vapor deposition process. An initiation-adhesion layer is formed over the carbon nanotubes and a metallic layer is then deposited on the initiation-adhesion layer and each layer is formed using a wet deposition process. In one embodiment, portions of the host substrate are used to form an electrochemical storage device that may be integrated with other formed electrochemical storage devices to create an interconnected battery array. The battery array may be formed as a woven sheet, panel, or other flexible structure depending upon the type of host substrate material. In one case, the host substrate material may be a flexible fibrous material that has multiple layers formed thereon to form a fiber battery, such as a lithium ion battery.

### CROSS-REFERENCE TO RELATED APPLICATIONS

This application claims benefit of U.S. provisional patent application Ser. No. 61/168,886 (Attorney Docket No. 12923L), filed Apr. 13, 2009, and U.S. provisional patent application No. 61/180,607, filed May 22, 2009 (Attorney Docket No. 12924L), both of which are herein incorporated by reference in their entirety. This application is related to U.S. patent application Ser. No. ______, filed Apr. 13, 2010 (Attorney Docket No. 12923.02).

### BACKGROUND OF THE INVENTION

1. Field of the Invention

Embodiments of the present invention generally relate to the formation of composite materials which include carbon nanotubes and nanofibers and, more specifically, to the formation of composite materials which include metallized carbon nanotubes and nanofibers formed on substrates. Embodiments of the present invention also relate to an apparatus and methods of forming lithium-ion batteries on composite materials using thin-film deposition processes.

2. Description of the Related Art

Carbon nanotubes and nanofibers possess many interesting and unique properties which make carbon nanotubes and nanofibers attractive for use in many potential applications, such as cold field emission, electrochemical energy storage, high-capacity hydrogen storage media, and composite material reinforcement, to name just a few. Some of the unique and interesting properties of carbon nanotubes include great strength, high electrical and thermal conductivity, large surface area-to-volume ratios, and thermal and chemical stability. The structures of carbon nanotubes and nanofibers give rise to many of their properties.

Fast-charging, high-capacity energy storage devices, such as supercapacitors and lithium-(Li) ion batteries, are used in a growing number of applications, including portable electronics, medical, transportation, grid-connected large energy storage, renewable energy storage, and uninterruptible power supply (UPS). In modern rechargeable energy storage devices, the current collector is made of an electric conductor. Examples of materials for the positive current collector (the cathode) include aluminum, stainless steel, and nickel. Examples of materials for the negative current collector (the anode) include copper (Cu), stainless steel, and nickel (Ni). Such collectors can be in the form of a foil, a film, or a thin plate, having a thickness that generally ranges from about 6 to 50 μm.

The active electrode material in the positive electrode of a Li-ion battery is typically selected from lithium transition metal oxides, such as LiMn₂O₄, LiCoO₂ and/or LiNiO₂, and includes electroconductive particles, such as carbon or graphite, and binder material. Such positive electrode material is considered to be a lithium-intercalation compound, in which the quantity of conductive material is in the range from 0.1% to 15% by weight.

Carbon nanotubes and nanofibers are graphitic nanofilaments with diameters ranging from about 0.4 nanometers to about 500 nanometers and lengths which typically range from a few micrometers to a few millimeters. Graphitic nanofilaments may be categorized according to at least four distinct structural types, namely, tubular, herringbone, platelet, and ribbon. The term “nanotube” may be used to describe the tubular structure whereas “nanofiber” may describe the non-tubular forms.

Carbon nanotubes are generally classified as single-walled carbon nanotubes and multi-walled carbon nanotubes. FIG. 1A is a schematic view of a single-walled carbon nanotube (SWCNT). The SWCNT 100 is a graphitic nanofilament which comprises a cylindrical carbon molecule that may be conceptualized as a one-atom thick sheet of graphite called graphene rolled into a seamless graphene tube 104 of diameter “d” and filament length “L.” The graphene tube 104 forms a cylindrical wall which is parallel to the filament axis direction. One or more of the nanotube ends 102 may be capped (see FIG. 2A) by additional carbon atoms. The diameter “d” may range from about 0.4 nanometers to a few nanometers and the filament length “L” may range from a few micrometers to a few millimeters, and the large length-to-diameter aspect ratio of the SWCNT 100 gives the nanotube a large surface area-to-volume ratio.

The rolled graphene layer or sheet of the SWCNT 100 comprises six-member hexagonal rings of carbon atoms held together by covalent sp2 bonds and these bonds combined with the tubular graphene structure impart extraordinary strength (tensile strength) and stiffness (elastic modulus) to carbon nanotubes. The SWCNT 100, for example, may have an average tensile strength of about 30 GPa and an elastic modulus of about 1 TPa compared to stainless steel which may have a tensile strength of about 1 GPa and an elastic modulus of about 0.2 TPa. Carbon nanotubes also have a fairly low density for a solid (about 1.3 g/cm3 for SWCNTs 100) and their strength-to-weight ratio is the highest of known materials. The electrical conductivity of the SWCNT 100 may be semiconducting or metallic depending upon how the graphene sheet is rolled to form the graphene tube 104, and metallic-type carbon nanotubes can carry electrical current densities orders of magnitude larger than those carried by the best conducting metals.

FIG. 1B is a schematic view of a multi-walled carbon nanotube (MWCNT). The MWCNT 110 may be conceptualized as one or more graphene tubes 104 of filament length “L” coaxially arranged about the SWCNT 100 of diameter “d.” The graphene tubes 104 form cylindrical walls which are parallel to the filament axis direction “A” and the walls are separated from each other by an interlayer spacing 116 of about 0.34 nanometers which approximates the distance between graphene layers in graphite. The number of tubes (three are shown) or cylindrical walls within the MWCNT 110 may range from two to fifty, or more. An outer nanotube 112 has a filament diameter “do” which may range from a few nanometers to several hundred nanometers or more depending upon the number of walls within the MWCNT 110.

The term “carbon nanotube” is typically used to describe a nanofilament which comprises one or more graphene layers or sheets which are parallel to the filament axis and which form tubular structures. The term “carbon nanofiber,” on the other hand, typically describes a nanofilament which comprises graphene layers which may or may not be parallel to the filament axis and which do not form tubular structures, although the structures may be formed so that the nanofibers are substantially round or polygonal in cross-section. Examples of nanofiber structures include herringbone, platelet, ribbon, stacked-cone, and other carbon nanofiber structures known in the art. Some nanofibers may have a hollow core or central hole along the filament axis of each nanofiber, while other nanofibers may have solid cores. The term “graphitic nanofilament” is used herein to refer to a carbon nanotube and/or carbon nanofiber. The graphitic nanofilaments may have overall shapes which include but are not limited to straight, branched, twisted, spiral, and helical.

FIG. 1C is a schematic view of a herringbone carbon nanofiber 120. The herringbone carbon nanofiber 120 comprises graphene sheets 121 which form an angle β with the filament axis direction “A”. The graphene sheets 121 are separated from each other by the interlayer spacing 116. A related nanofiber consists of graphene layers or sheets shaped as cones which are stacked along the length of the fiber to form a stacked-cone nanofiber (not shown). The graphene cones are separated from each other by the interlayer spacing 116.

FIG. 1D is a schematic view of a platelet carbon nanofiber 130. The platelet carbon nanofiber 130 comprises small graphene sheets 121 in the form of stacked platelets which are perpendicular to the filament axis direction “A”. The platelets are separated by the interlayer spacing 116 and the platelets may be polygonal or round in shape. A typical platelet nanofiber size is around 100 nanometers in width.

FIG. 1E is a schematic view of a ribbon carbon nanofiber 140. The ribbon carbon nanofiber 140 comprises flat graphene sheets 121 which are substantially parallel to the filament axis direction “A” and are separated by the interlayer spacing 116. The flatness of the graphene layers in the ribbon structure distinguish it from the tubular layers in the nanotube structure, although both structures have graphene layers which are parallel to the filament axis direction “A”.

The tubular structure of carbon nanotubes imparts to the nanotubes some unique properties which are not shared by carbon nanofibers. Carbon nanofibers are more closely related to graphite which consists of graphene layers held together by interlayer van der Waals forces which are much weaker than the intra-layer bonding forces within each graphene layer. The properties of carbon nanofibers are determined by the combination of the strong intra-layer bonds and the weaker interlayer bonds of the graphene structures, whereas the properties of carbon nanotubes are determined more by the strong intra-layer bonds in the tubular graphene structures. As a result, some of the properties of carbon nanofibers may be characterized as being intermediate to the properties of carbon nanotubes and graphite.

The properties of carbon nanotubes and nanofibers make their potential use in various applications desirable. The low density, high mechanical strength, electrical conductivity, and thermal conductivity of carbon nanotubes make them attractive for potential use in composite material applications. Carbon nanofibers also have fairly low densities and may be used to improve the mechanical strength and electrical conductivity of composite materials, although carbon nanofibers typically possess much less strength than carbon nanotubes.

Carbon nanotubes and nanofibers are also attractive for potential use in energy storage applications such as electrodes for lithium-ion batteries, supercapacitors, or fuel cells. The large length-to-diameter aspect ratios of carbon nanotubes and nanofibers provide large surface areas per nanofilament and many nanofilaments can form large surface areas which may provide improved charge storage capabilities for electrodes. Carbon nanofibers, in particular, have many interlayer spacings 116 (see FIGS. 1C-1E) through which small ions may enter and intercalate between the graphene layers, and this property makes carbon nanofibers attractive for electrode applications.

The many potential applications of carbon nanotubes and nanofibers make their functionalization desirable. The functionalization may include forming carbon nanotubes and nanofibers on various types of substrates to create composite materials which combine the properties of each substrate with the properties of the carbon nanotubes and/or nanofibers. It may also be desirable to deposit additional materials, such as metals, for example, onto the carbon nanotubes or nanofibers to enhance or modify various properties (e.g., electrical conductivity, strength, stiffness, thermal expansion, density, etc.) of the composite material.

Carbon nanotubes are typically formed using laser ablation, arc discharge, or chemical vapor deposition (CVD). The techniques of laser ablation and arc discharge typically use higher processing temperatures than CVD and the higher temperatures facilitate the formation of nanotubes. However, laser ablation and arc discharge form nanotubes separately (i.e., not directly on substrates) and require post-production processing (e.g., recovery, sorting, purification) of the nanotubes before they can be applied to substrates. In contrast, CVD methods allow the formation of carbon nanotubes and nanofibers directly onto substrates. Additionally, CVD methods can produce nanotubes and nanofibers at lower temperatures while providing control over the types and sizes of carbon nanotubes and nanofibers produced. Thus, CVD may provide a cost effective means for forming carbon nanotubes or nanofibers on substrates.

The use of various types of substrates in composite materials may increase the range of applications for the composite materials. The substrates may include wafers, panels, sheets, webs, and fibers, for example. Thus, it is desirable to provide a cost effective means for forming carbon nanotubes and nanofibers on various types of substrates. Additionally, it is desirable to provide a cost effective means for the metallization of carbon nanotubes and nanofibers formed on various types of substrates used in composite materials.

Therefore, a need exists for a cost effective method and apparatus for the formation of composite materials which comprise metallized carbon nanotubes and/or nanofibers formed on various types of substrates. Accordingly, there is a need in the art for faster charging, higher capacity energy storage devices that are smaller, lighter, and can be more cost effectively manufactured.

### SUMMARY OF THE INVENTION

Embodiments of the present invention provide a cost effective method and apparatus for the formation of composite materials which comprise metallized carbon nanotubes and/or nanofibers formed on various types of substrates.

In one embodiment, an electrode comprises a host substrate, a nanofilament layer comprising graphitic nanofilaments formed on a surface of the host substrate, an initiation-adhesion layer over the nanofilament layer, and a metallic layer on the initiation-adhesion layer.

In one embodiment, a method is disclosed for forming a electrode. The method comprises forming a nanofilament layer comprising graphitic nanofilaments on a surface of a host substrate, wherein said layer is formed using chemical vapor deposition, forming an initiation-adhesion layer over the nanofilament layer, and depositing a metallic layer on the initiation-adhesion layer.

In one embodiment, an apparatus for forming a electrode is disclosed. The apparatus comprises a nanofilament growth apparatus adapted for growing graphitic nanofilaments on a host substrate, one or more processing stations adapted for metallizing the graphitic nanofilaments, and a means for supporting, guiding, and moving the host substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a schematic view of a single-walled carbon nanotube.

FIG. 1B is schematic view of a multi-walled carbon nanotube.

FIG. 1C is schematic view of a herringbone carbon nanofiber.

FIG. 1D is schematic view of a platelet carbon nanofiber.

FIG. 1E is schematic view of a ribbon carbon nanofiber.

FIG. 2A is a schematic view of graphitic nanofilaments formed by two catalytic CVD growth processes which use a catalyst support according to one embodiment of the invention.

FIG. 2B is a schematic view of a catalyst film on a catalyst support according to one embodiment of the invention.

FIG. 2C is a schematic view of catalyst particles formed from the catalyst film shown in FIG. 2B according to one embodiment of the invention.

FIG. 2D is a schematic view of aligned graphitic nanofilaments in the presence of an electric field according to one embodiment of the invention.

FIG. 2E is another schematic view of aligned graphitic nanofilaments in the presence of an electric field according to one embodiment of the invention.

FIG. 2F is a schematic view of aligned graphitic nanofilaments on a catalyst support 205 with a porous surface according to one embodiment of the invention.

FIG. 3A is a schematic top view of a host substrate according to one embodiment described herein according to one embodiment of the invention.

FIG. 3B is a schematic top view of a host substrate according to another embodiment described herein according to one embodiment of the invention.

FIG. 4A is a simplified schematic view of an apparatus for growing graphitic nanofilaments on a host substrate according to one embodiment described herein.

FIG. 4B is a simplified schematic view of another embodiment of the apparatus shown in FIG. 4A according to one embodiment of the invention.

FIG. 4C is a simplified schematic view of another apparatus for growing graphitic nanofilaments on a host substrate according to one embodiment described herein.

FIG. 4D is a simplified schematic view of another embodiment for the apparatus shown in FIG. 4C according to one embodiment of the invention.

FIG. 4E is a simplified schematic view of an apparatus for growing graphitic nanofilaments on a host substrate according to another embodiment described herein.

FIG. 5A is a simplified cross-sectional view of a nanofilament composite material comprising metallized graphitic nanofilaments on a host substrate according to one embodiment described herein.

FIG. 5B is another embodiment described herein of the nanofilament composite material shown in FIG. 5A according to one embodiment of the invention.

FIG. 5C is a simplified cross-sectional view of an electrochemical storage device which includes the nanofilament composite material shown in FIG. 5A according to one embodiment described herein.

FIG. 5D is a simplified cross-sectional view of a portion of an electrochemical storage device which includes the nanofilament composite material according to one embodiment described herein.

FIG. 5E is a simplified cross-sectional view of a portion of an electrochemical storage device which includes the nanofilament composite material according to one embodiment described herein.

FIG. 6A illustrates a process for forming the nanofilament composite material shown in FIGS. 5A and 5B according to one embodiment described herein.

FIG. 6B illustrates a process for one of the steps shown in FIG. 6A according to one embodiment described herein.

FIG. 7A is a simplified schematic view of an apparatus for forming the nanofilament composite material shown in FIGS. 5A and 5B according to one embodiment described herein.

FIG. 7B is a simplified schematic view of another embodiment described herein for the apparatus shown in FIG. 7A according to one embodiment of the invention.

FIG. 7C is a simplified schematic view of an apparatus for depositing materials onto graphitic nanofilaments formed on a host substrate according to one embodiment described herein.

FIG. 7D is a simplified schematic view of an apparatus for depositing materials onto graphitic nanofilaments formed on a host substrate according to another embodiment described herein.

FIG. 7E is a simplified schematic view of an apparatus for depositing materials onto graphitic nanofilaments formed on a host substrate according to one embodiment described herein.

FIG. 7F is a simplified schematic view of an apparatus for depositing materials onto graphitic nanofilaments formed on a host substrate according to another embodiment described herein.

FIG. 7G is a simplified schematic view of an apparatus for electrochemically depositing materials onto on a host substrate according to another embodiment described herein.

FIG. 7H is a simplified schematic view of an apparatus for electrochemically depositing multiple material layers onto a host substrate according to another embodiment described herein.

FIG. 8 illustrates one embodiment described herein for the formation process shown in FIG. 6A according to one embodiment of the invention.

FIG. 9 illustrates another embodiment described herein for the formation process shown in FIG. 6A according to one embodiment of the invention.

FIG. 10 illustrates one embodiment described herein for the formation process shown in FIG. 6A according to one embodiment of the invention.

FIG. 11 illustrates another embodiment described herein for the formation process shown in FIG. 6A according to one embodiment of the invention.

FIG. 12 illustrates one embodiment described herein for the formation process shown in FIG. 6A according to one embodiment of the invention.

To facilitate understanding, identical reference numerals have been used, where possible, to designate identical elements that are common to the figures. It is contemplated that features of one embodiment may be incorporated in other embodiments without further recitation.

### DETAILED DESCRIPTION

The present invention generally provides a cost effective method and apparatus for forming graphitic nanofilaments (i.e., carbon nanotubes and/or nanofibers) on various types of substrates and then coating the graphitic nanofilaments with metal to form composite materials which include metallized graphitic nanofilaments. The substrates may comprise various materials and structural forms such as fibers, sheets of woven fibers, or panels, for example.

The composite material containing metallized graphitic nanofilaments may be used for various applications, such as a large surface area electrode or current collector in an electrochemical storage device, for example. The electrochemical storage device (e.g., battery, supercapacitor) may be formed by depositing additional material layers onto the metallized graphitic nanofilaments of the composite material. In one embodiment, portions of the resulting electrochemical storage device may be integrated into a woven sheet, panel, or other flexible structure depending upon the type of substrate used to form the composite material. In one embodiment, the composite material is a flexible fibrous material that is used to form at least one electrode in a battery, such as a lithium ion battery. In one configuration, a plurality of formed flexible fibers comprising the composite material are woven or bonded together to form a plurality of separate electrodes in a larger electrochemical device.

CVD Growth Processes for Graphitic Nanofilaments

In one embodiment, the composite material containing metallized graphitic nanofilaments may be formed using different deposition and processing techniques. One desirable processing technique that can be used to form the metallized graphitic nanofilaments is a chemical vapor deposition process (CVD). The chemical vapor deposition (CVD) techniques used to form graphitic nanofilaments may be generally categorized into two types: catalytic and non-catalytic. The methods which use catalyst materials to facilitate and help control the growth of graphitic nanofilaments are referred to as catalytic CVD methods. The methods which use no catalyst materials for graphitic nanofilament growth are referred to as non-catalytic or pyrolytic CVD methods since only heating, and not catalysis, typically drives nanofilament growth. The catalytic CVD methods often provide greater control over graphitic nanofilament growth than non-catalytic methods. Various methods of graphitic nanofilament growth are described by K. Teo et al., in “Catalytic Synthesis of Carbon Nanotubes and Nanofibers,” Encyclopedia of Nanoscience and Nanotechnology, Volume X, pg. 1-22, American Scientific Publishers, 2003.

The use of substrates for the catalytic CVD growth of graphitic nanofilaments provides some advantages over “floating” catalytic methods which do not require substrates or supporting surfaces for the catalyst materials. First, in some applications, it may be desirable to form graphitic nanofilaments directly on a surface which forms part of a functional structure. For example, it may be desirable to deposit graphitic nanofilaments at the bottom of a small aperture on a substrate to form a field emission electron source, and space limitations may make direct growth of the graphitic nanofilaments on a surface of the aperture the only practical means to achieve the deposition. Second, the use of a substrate makes it possible to anchor catalyst nanoparticles to a surface in order to control the size of the catalyst nanoparticles. At typical CVD nanofilament growth temperatures (e.g., 500° C. to 900° C.), the catalyst nanoparticles (typically metal) have sufficient mobility and cohesive forces to coalesce into larger particles. The anchoring of the catalyst nanoparticles can prevent such coalescence and help control the diameters of the graphitic nanofilaments. Third, the use of a substrate can facilitate the alignment of the graphitic nanofilaments.

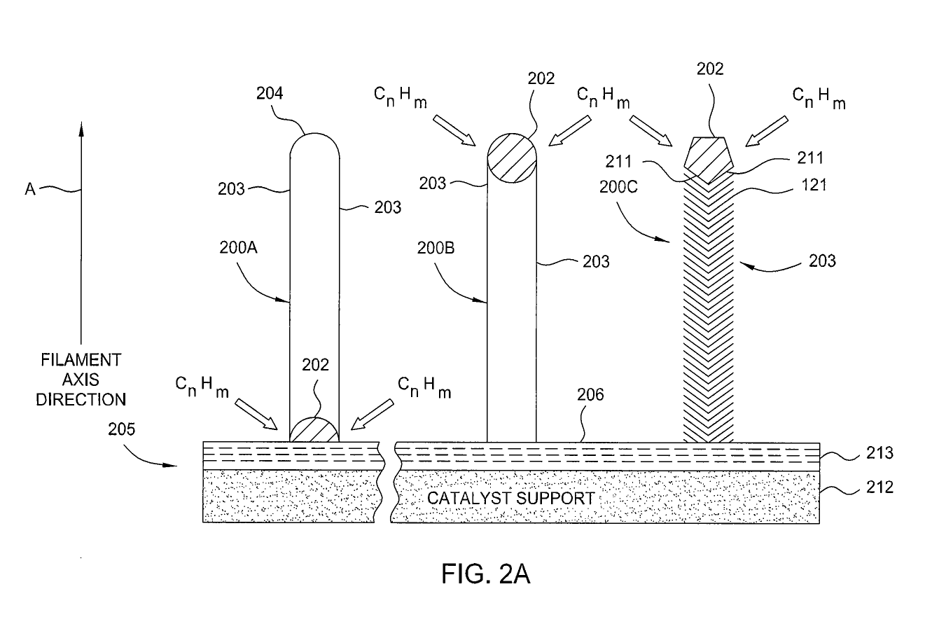

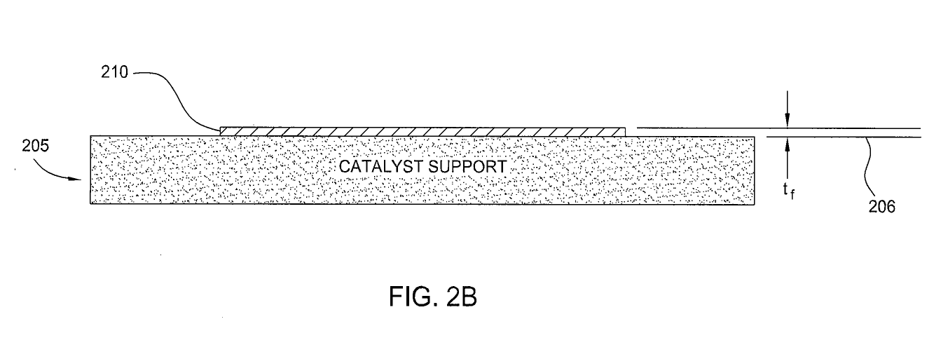

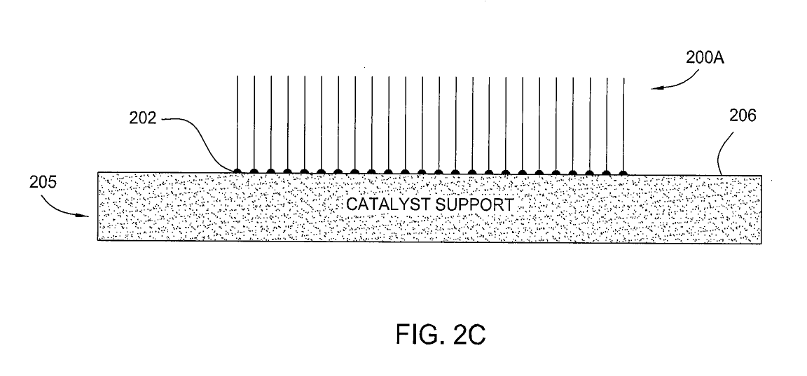

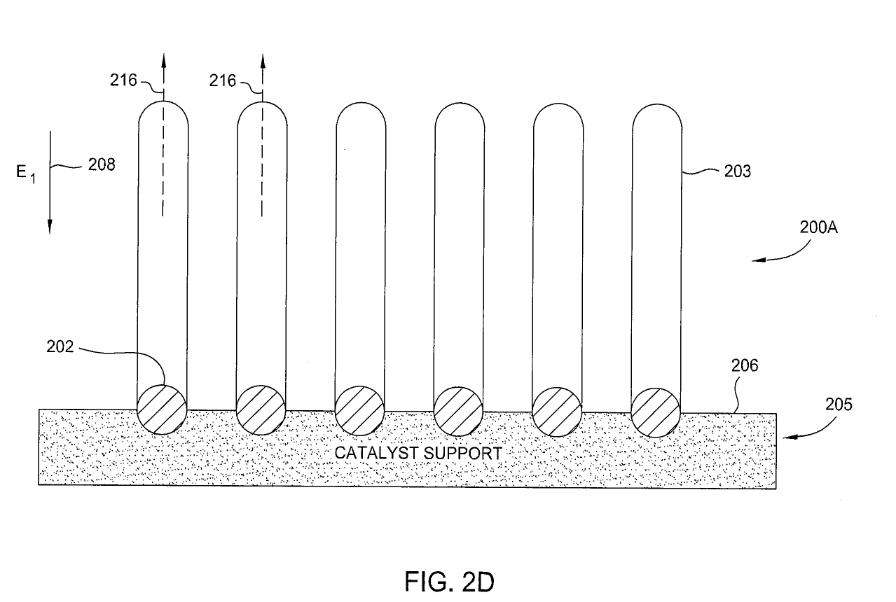

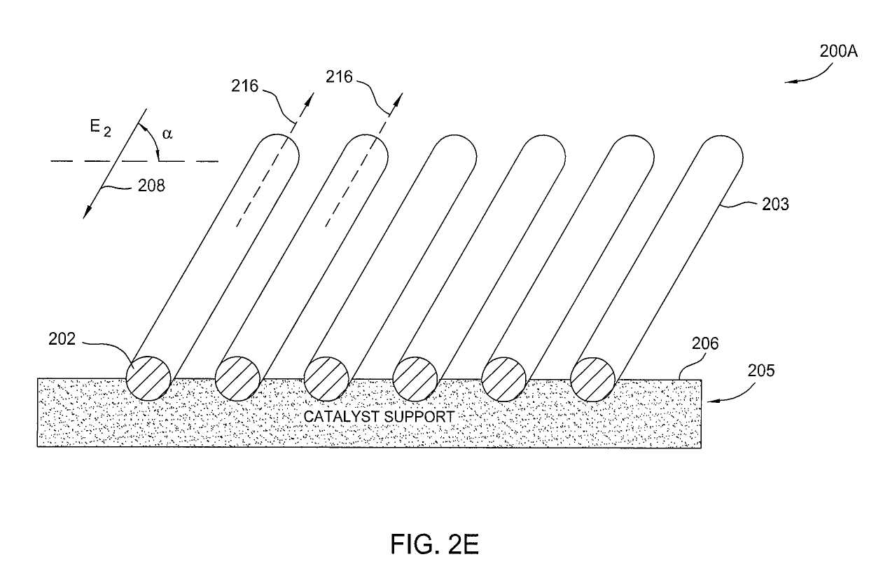

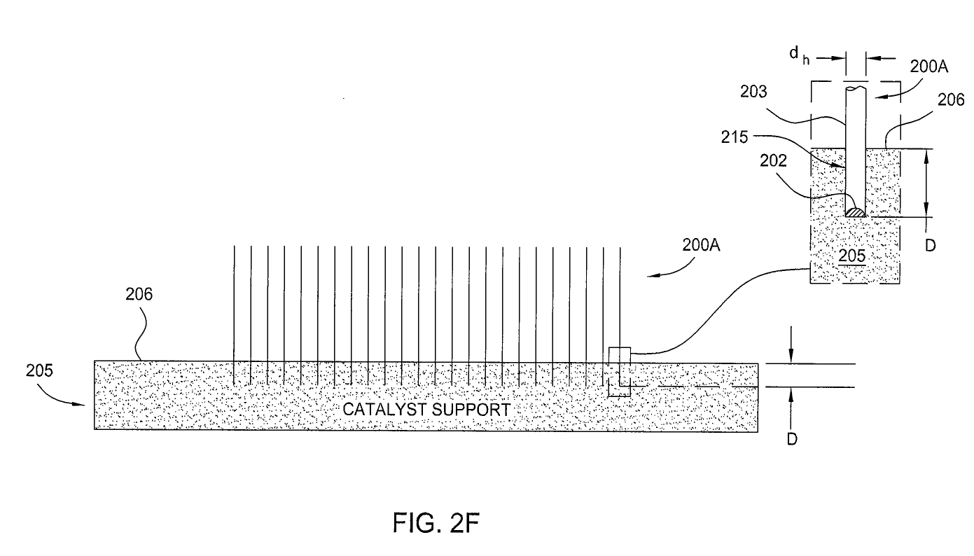

FIG. 2A is a schematic view of graphitic nanofilaments formed by two catalytic CVD growth processes which use a catalyst support 205. The CVD growth of carbon nanotubes involves heating catalyst particles 202 to a high temperature and flowing a carbon source gas, such as a hydrocarbon “CₙHₘ”, carbon monoxide, or other carbon-containing gas over the catalyst particles 202 for a period of time. The catalyst particles 202 reside on a support surface 206 of the catalyst support 205. The catalyst particles 202 are typically nanometer scale in size, and the diameters or widths of the graphitic nanofilaments are often closely related to the sizes of the catalyst particles 202.

The catalyst particles 202 comprise any suitable catalyst materials for graphitic nanofilament growth, but preferred materials are the transition metals and transition metal oxides. The catalyst materials may include but are not limited to iron, cobalt, nickel, copper, silver, magnesium, ruthenium, rhodium, iridium, platinum, palladium, molybdenum, tungsten, chromium and alloys, oxides, and combinations thereof. Combinations or mixtures of catalyst materials which may be used include but are not limited to iron-nickel, iron-molybdenum, iron-cobalt, cobalt-nickel, and cobalt-molybdenum. Preferred catalysts include iron, cobalt, nickel and alloys thereof.

The catalytic CVD growth of graphitic nanofilaments typically involves the catalytic dissociation of a hydrocarbon source gas into carbon and hydrogen at the surfaces of a transition metal particle which acts as a catalyst. Not wishing to be bound by theory, it is believed that, at high temperatures, the carbon has solubility in the transition metal particle and the carbon dissolves into and diffuses through the metal to form a carbon saturated metal-carbon solution. The carbon precipitates from the saturated solution at one or more surfaces of the metal particle to grow a graphitic nanofilament with a diameter substantially equal to the diameter of the metal particle.

Referring to FIG. 2A, the catalytic growth of graphitic nanofilaments may proceed by a tip-growth or base-growth process. If the interaction between the catalyst particle 202 and the catalyst support 205 is strong, the precipitation of carbon atoms may produce a base-growth nanotube 200A with tubular nanofilament walls 203 that grow up around the catalyst particle 202 which remains attached to the catalyst support 205 at the base of the nanotube. The base-growth nanotube 200A typically forms a hemispherical cap 204 of carbon atoms opposite the base of the nanotube. Alternately, if the interaction between the catalyst particle 202 and the catalyst support 205 is weak, the nanotube may grow so as to lift the catalyst particle 202 away from the catalyst support 205 and form a tip-growth nanotube 200B with the catalyst particle 202 located at the tip of the nanotube. The nanotubes shown in FIG. 2A are single-walled, but multi-walled structures may be formed by similar growth processes. The graphitic nanofilament grows in the filament axis direction “A” as carbon precipitates from one or more surfaces of the catalyst particle 202 for both the tip-growth and base-growth processes.

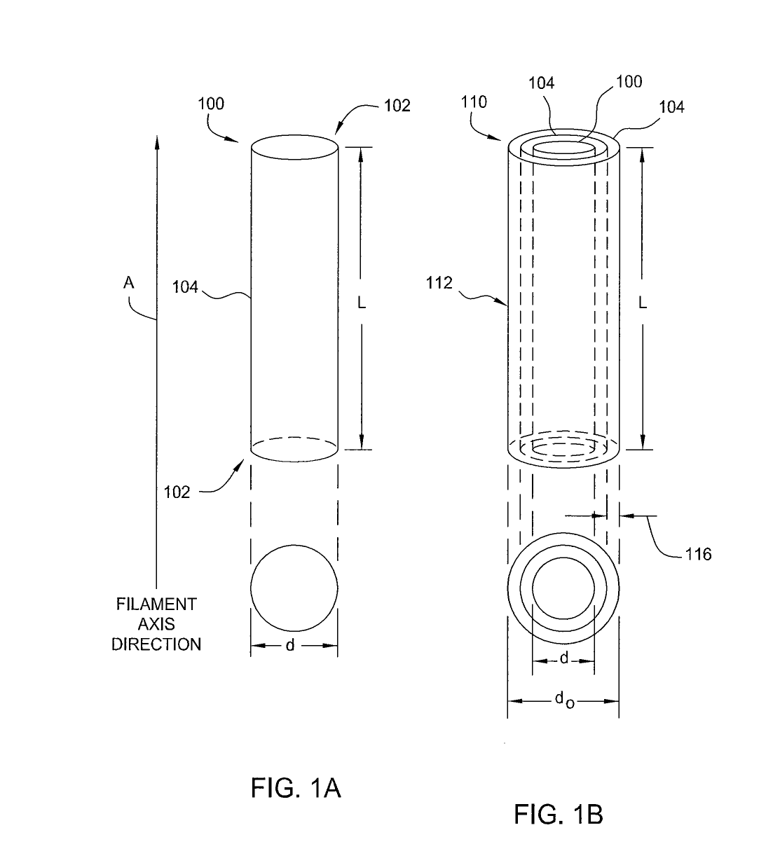

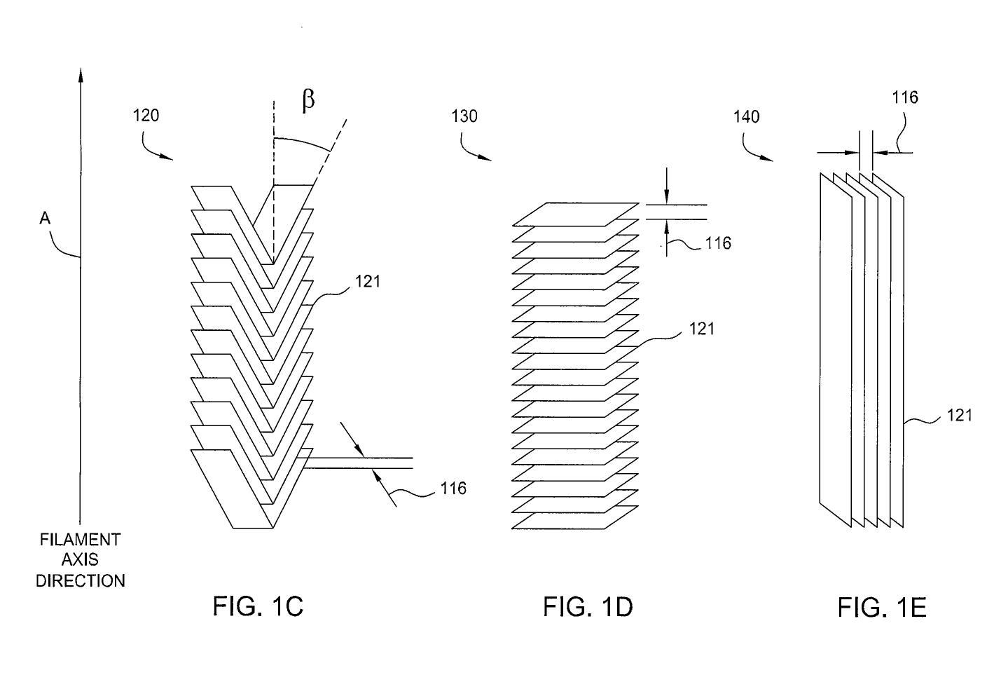

Carbon nanofibers may also grow by a tip-growth or base-growth process depending upon the strength of interaction between the catalyst particle 202 and catalyst support 205. A carbon nanofiber may form when the catalyst particle 202 has one or more faceted or planar surfaces 211, whereas the catalyst particle 202 may be more spherical in shape for the formation of a carbon nanotube. A tip-growth nanofiber 200C of the herringbone-type (see FIG. 1C) may be formed when the catalyst particle 202 has two planar surfaces 211 at an angle to each other. Carbon precipitates at the planar surfaces 211 to form graphene sheets 121 parallel to the planar surfaces 211 and at an angle to the filament axis direction. The edges of the graphene sheets 121 form nanofilament walls 203 for the tip-growth nanofiber 200C.

In one embodiment, the catalyst support 205 comprises a support material 212 covered with a buffer layer 213. The support material 212 may comprise aluminum oxide, silicon oxide, silicon, glass, metals or other materials which are stable in the range of temperatures used for graphitic nanofilament growth. The buffer layer 213 comprises a buffer material (e.g., titanium nitride, silicon dioxide) which prevents the catalyst particles 202 from reacting or alloying with the support material 212 at the nanofilament growth temperature. Such reacting or alloying of the catalyst particles 202 with the support material 212 may be undesirable since it can effectively reduce or consume the catalyst particles 202 and thereby reduce the growth yield of graphitic nanofilaments. The buffer layer 213 may also act as a diffusion barrier to prevent the catalyst particles 202 from diffusing into the support material 212. In one embodiment, the catalyst support 205 comprises a buffer layer 213 which is patterned to cover some areas of the support material 212 and not cover other areas of the support material 212. In one embodiment, the buffer layer 213 is suitably adapted to allow limited reaction between the catalyst particles 202 and support material 212. In another embodiment, the catalyst support 205 comprises the support material 212 without the buffer layer 213.

Catalyst Preparation

Various methods may be used to prepare the catalysts and the catalyst supporting surfaces used for graphitic nanofilament growth. The catalyst particles 202 may be deposited onto the catalyst support 205 using wet or dry deposition techniques. Dry deposition techniques include but are not limited to sputtering, thermal evaporation, and CVD, and wet deposition techniques include but are not limited to the techniques of wet catalyst, colloidal catalyst solutions, sol-gel, electrochemical plating, and electroless plating.

The wet catalyst method uses a catalyst solution which may comprise soluble salts of one or more catalyst materials (e.g., transition metals) in a solvent. The catalyst solution is applied to the catalyst support 205 using spray coating, spin coating, inkjet printing, or other application techniques which provide the desired control for depositing the catalyst solution onto the catalyst support 205. The catalyst solution may then be dried to leave catalyst particles 202 on the catalyst support 205. The concentration of the catalyst solution may be adjusted to control the density of graphitic nanofilaments grown on the catalyst support 205.

In one embodiment, the catalyst solution may be dried by calcinations (i.e., heating in air) so that oxides of the catalyst metal are formed leaving metal oxide nanoparticles deposited on the catalyst support 205. The metal oxide nanoparticles may then be reduced to metal nanoparticles which form the catalyst particles 202. The reduction may be performed before or during graphitic nanofilament growth. Hydrogen gas or other gases may be used to reduce the metal oxide nanoparticles to metal nanoparticles. In another embodiment, the metal oxide nanoparticles are not reduced and are used directly as the catalyst particles 202.

The wet catalyst method may be modified by replacing the catalyst solution with a colloidal catalyst solution which comprises colloidal particles of catalyst material which may comprise one or more metals or metal oxides. The colloidal catalyst solution may be applied to the catalyst support 205 using similar techniques used for the wet catalyst method. One advantage of using colloidal catalyst solutions is that the diameters (or widths) of the catalyst particles 202 can be controlled within a fairly narrow range down to diameters of a few nanometers, and such control over the sizes of the catalyst particles 202 allows good control over the diameters of the graphitic nanofilaments. In one embodiment, the colloidal catalyst solution and catalyst support 205 may also be configured to deposit the catalyst particles 202 onto the catalyst support 205 using an electrophoretic deposition process (i.e., attraction of charged catalyst particles 202 by a charged catalyst support 205).

The catalyst particles 202 may also be applied to a catalyst support 205 using the sol-gel method which may be used to produce catalyst impregnated films, aerogels, fibers, ceramics, and other materials which may be used to form a catalyst support 205. The sol-gel method can produce structures with very high surface area, high porosity, and very low density and these characteristics can produce high yield growth of graphitic nanofilaments.

In another method, the catalyst particles 202 may also be deposited onto the catalyst support 205 using electrochemical plating which uses an electrolyte containing a catalyst metal salt. The catalyst support 205 is suitably adapted to have an electrically conductive support surface 206. The current density and deposition time may be controlled during electrochemical deposition to control the density of the catalyst particles 202 deposited on the support surface 206 and thereby control the density of graphitic nanofilaments formed on the catalyst support 205.

An alternate method for forming catalyst particles 202 on a catalyst support 205 begins by depositing a thin layer or film of catalyst material on the catalyst support 205. FIG. 2B is a schematic view of a catalyst film 210 on a catalyst support 205. The catalyst film 210 may be deposited by sputtering, thermal evaporation, CVD or other dry deposition techniques and the film may comprise any of the catalyst materials described herein for the catalyst particles 202. In another embodiment, the catalyst film 210 may be deposited using electrochemical or electroless deposition. The catalyst film 210 may comprise one or more layers of different catalyst materials, such as a layer of molybdenum over a layer of iron, for example, although any number of layers and materials may be used. Alternately, the catalyst film 210 may comprise layers of catalyst materials overlying layers of non-catalyst materials. The non-catalyst layers may be used to control the surface properties of the catalyst layers and the growth yield of graphitic nanofilaments. The catalyst film 210 has a film thickness “tf” which may range from a few nanometers to several tens of nanometers or more.

FIG. 2C is a schematic view of catalyst particles 202 formed from the catalyst film 210 shown in FIG. 2B. The catalyst film 210 may be sufficiently heated so that the metallic catalyst film 210 breaks up and coalesces into catalyst particles 202. The heated catalyst film 210 may form particles due to the surface mobility and strong cohesive forces of the metal atoms. The catalyst particles 202 may then catalyze the growth of base-growth (base-growth nanotubes 200A are shown) or tip-growth graphitic nanofilaments. The heating or annealing of the catalyst film 210 to form the catalyst particles 202 may occur before or during the nanofilament growth process.

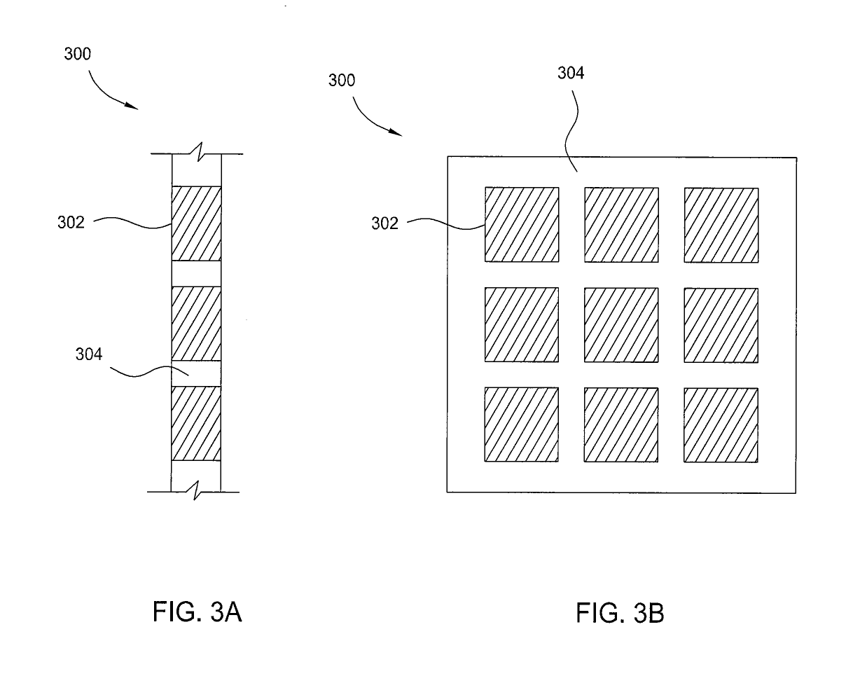

The sizes of the catalyst particles 202 may be controlled by controlling the parameters of film thickness “tf”, temperature, and the annealing time of the catalyst film 210, although the particle sizes may follow a distribution since the coalescence process is random. The aforementioned parameters are typically controlled so that the catalyst particles 202 are nanometer-scale in size. Larger catalyst particles 202 may result by increasing the film thickness “tf”, temperature, and annealing time of the catalyst film 210 due to increased surface mobility, migration, and availability of metal catalyst atoms. The catalyst film 210 may be patterned (see FIGS. 3A and 3B) on a surface of the catalyst support 205 using various masking, lithography, etching, or other techniques to form lines, dots, rectangles, or other patterns for the catalyst film 210, and such patterning may facilitate the controlled formation of the catalyst particles 202.

The catalyst particles 202 shown in FIG. 2C may also be formed by roughening the surface of a thick catalyst film 210. The surface roughening may be accomplished through mechanical (e.g., abrasion, plasma etching, ion bombardment) and/or electrochemical (e.g., wet etching) means to generate the catalyst particles 202. Alternately, no catalyst film 210 may be used and the catalyst particles 202 may also be formed by roughening the support surface 206 of a catalyst support 205 which comprises catalyst material. In another method, the metal surface of the catalyst film 210 or catalyst support 205 is oxidized by heating or other means to form a porous metal oxide surface and then the metal oxide is reduced using a reducing gas (e.g., hydrogen) to form metal catalyst particles 202. The reduction of the metal oxide may occur before or during the nanofilament growth process.

Graphitic nanofilaments may also be formed using the “floating catalyst” method in which catalyst-containing materials are injected directly into a graphitic nanofilament growth chamber. The catalyst-containing materials may be injected before, during, or after the injection of a carbon source gas. The catalyst-containing materials may comprise the catalyst particles 202 or catalyst precursors from which the catalyst particles 202 are formed.

The catalyst precursors may comprise liquid catalyst mixtures, organometallic catalyst compounds, or other materials which contain catalysts. The liquid catalyst mixtures may comprise solutions, suspensions, or colloids of catalyst materials. The organometallic catalyst compounds may include but are not limited to iron pentacarbonyl, iron (II) phthalocyanine, ferrocene, nickelocene, cobaltocene, and other metallocenes. The catalyst precursors may be injected in either the gas, liquid, or solid phase using atomizers, syringe pumps, showerheads or other injecting means. After injection, the catalyst precursors may be converted into catalyst particles 202 by various means such as heating, reducing, decomposing, vaporizing, condensing, and sublimating, for example.

In the floating catalyst method, a graphitic nanofilament may grow from the catalyst particle 202 as the particle falls from the top to the bottom of the growth chamber or after the catalyst particle 202 has come to rest upon a surface within the chamber. If a substrate is included within the growth chamber, many catalyst particles 202 may come to rest upon the surface of the substrate and graphitic nanofilaments may form on the substrate surface. The floating catalyst method may, under certain conditions, be used to form many densely packed and aligned graphitic nanofilaments on the surface of a substrate.

CVD Growth Parameters for Graphitic Nanofilaments

The graphitic nanofilament type (nanotube or nanofiber), structure (single-walled, multi-walled, herringbone, etc.), diameter, length and alignment may be controlled by controlling the CVD growth parameters. The growth parameters include but are not limited to carbon source gas, carrier gas, growth temperature, growth pressure, and growth time. For catalytic CVD growth, additional growth parameters may include catalyst parameters such as catalyst size, shape, composition, and catalyst precursors. The parameter ranges and options for catalytic CVD growth, excluding catalyst parameters, may, in general, be applicable to the non-catalytic CVD growth of graphitic nanofilaments, although higher temperatures may be used for the non-catalytic CVD methods.

Generally, the temperatures for the catalytic CVD growth of graphitic nanofilaments may range from about 300 degrees Celsius (° C.) to about 3,000 degrees Celsius (° C.), but preferably from about 600° C. to about 1,200° C., although temperatures lower than 600° C. may be used, especially if the CVD growth is plasma enhanced. The growth pressures may range from about 0.1 Torr to about 1 atmosphere, but more preferably from about 0.1 Torr to about 100 Torr, although lower or higher pressures may also be used. In another embodiment, the growth pressures are above atmospheric pressure, and may range from about 1 atmosphere to about 10 atmospheres. The growth time or “residence time” depends in part on the desired graphitic nanofilament length, with longer growth times producing longer lengths. The growth time may range from about ten seconds to many hours, but more typically from about ten minutes to several hours. In one embodiment, the growth time is in a range between about 1 minute and about 5 minutes.

The carbon source gas used for graphitic nanofilament growth may include but is not limited to ethylene, propylene, acetylene, benzene, toluene, ethane, methane, butane, propane, hexane, methanol, ethanol, propanol, isopropanol, carbon monoxide, acetone, oxygenated hydrocarbons, low-molecular-weight hydrocarbons, high-molecular weight hydrocarbons or combinations thereof. In general, the carbon source gas may comprise any carbon-containing gas or gases, and the carbon source gas may be obtained from liquid or solid precursors for the carbon-containing gas or gases. An auxiliary gas may be used with the carbon source gas to facilitate the growth process. The auxiliary gas may comprise one or more gases, such as carrier gases, inert gases, reducing gases (e.g., hydrogen, ammonia), dilution gases, or combinations thereof, for example. The term “carrier gas” is sometimes used in the art to denote inert gases, reducing gases, and combinations thereof. Some examples of carrier gases are hydrogen, nitrogen, argon, and ammonia.

Nanofilament Alignment

The CVD growth parameters for graphitic nanofilament growth may also include parameters which facilitate the alignment of the graphitic nanofilaments on a substrate. The alignment parameters may include but are not limited to electric field direction and intensity, catalyst particle density, and substrate pore orientation.

FIG. 2D is a schematic view of aligned graphitic nanofilaments in the presence of an electric field. An electric field “E1” with a field direction 208 may be applied during graphitic nanofilament growth to facilitate the alignment of the nanofilaments. The electric field “E1” is substantially perpendicular to the support surface 206 as indicated by the field direction 208. Each graphitic nanofilament (base-growth nanotubes 200A are shown) has a nanofilament axis 216 (only two are shown) which indicates the orientation or alignment direction of the nanofilament. The graphitic nanofilaments may align themselves parallel to the electric field “E1” so that each nanofilament axis 216 is substantially parallel to the field direction 208. The electric field “E1” may be provided by a plasma generator which is used in a plasma enhanced chemical vapor deposition (PECVD) growth process. In one configuration, the electric field E1 is created between a capacitively coupled gas delivery showerhead that is disposed above and in a parallel relationship to a grounded, or electrically biased, substrate support over which the support surface 206 of the catalyst support 205 is disposed. One advantage of using an electric field for the alignment of the nanofilaments is that the nanofilaments may be aligned independently of any support surface topography. Another advantage of using an electric field is that the field intensity may be adjusted to help facilitate alignment, and a stronger electric field may provide more uniform alignment of the nanofilaments. The nanofilaments are sometimes said to be “vertically aligned” when the nanofilaments are substantially perpendicular to the support surface 206, as shown in FIG. 2D.

FIG. 2E is another schematic view of aligned graphitic nanofilaments in the presence of an electric field. An electric field “E2” with a field direction 208 has a direction angle “α” with respect to the support surface 206, and the direction angle “α” may be adjusted to control the alignment of the graphitic nanofilaments relative to the support surface 206 during nanofilament growth. The nanofilament axis 216 of each graphitic nanofilament is aligned substantially parallel to the field direction 208 at the direction angle “α.” For direction angles “α” of 90 degrees or 270 degrees (measured counterclockwise), the nanofilament alignment may be substantially perpendicular to the support surface 206. For direction angles “α” of zero degrees or 180 degrees, the nanofilament alignment may be substantially parallel to the support surface 206.

Graphitic nanofilaments may also be aligned in the absence of applied electric fields. During nanofilament growth, the nanofilament walls 203 of neighboring nanofilaments may interact with each other through Van der Waals forces which can keep the nanofilaments aligned parallel to each other and perpendicular (see FIG. 2D) to the support surface 206, resulting in the formation of aligned graphitic nanofilaments. The alignment of graphitic nanofilaments in the absence of electric fields may require nanofilament densities exceeding 104 nanofilaments per square millimeter of support surface 206. The alignment of graphitic nanofilaments due to dense packing is sometimes referred to as “self-oriented” or “self-assembled” growth.

FIG. 2F is a schematic view of aligned graphitic nanofilaments on a catalyst support 205 with a porous surface. The support surface 206 comprises a plurality of nanopores 215 so that the catalyst support 205 may function as a growth template for graphitic nanofilaments. The density, diameter, and alignment of the nanopores 215 are controlled so that the density, diameter, and alignment of the graphitic nanofilaments (base-growth nanotubes 200A are shown) may also be controlled. The nanopore density is the number of nanopores 215 per unit area of the support surface 206, and the nanopores 215 may be aligned (vertical alignment is shown) as desired relative to the support surface 206. The nanopores 215 may comprise cylindrical holes, each hole having a diameter “dh” which ranges from a few nanometers to hundreds of nanometers and a depth “D” which may range from a few micrometers to hundreds of micrometers.

The nanopores 215 may be created using any suitable means which can provide the desired density, diameter, and alignment of the nanopores 215. For example, the catalyst support 205 or a portion thereof may comprise aluminum which is electrochemically processed (e.g., anodized) to produce a porous aluminum oxide support surface 206 having nanopores 215 which are substantially vertical in alignment. During processing, the electrochemical processing parameters may be varied to control the diameter “dh”, depth “D”, and density of the nanopores 215.

The graphitic nanofilaments are grown within the nanopores 215 and the density, diameter, and alignment of the nanofilaments may closely reproduce the density, diameter, and alignment of the nanopores 215. Catalyst particles 202 may be deposited within the nanopores 215 to enable catalytic nanofilament growth (either base-growth or tip-growth). Alternately, the growth of the graphitic nanofilaments within the nanopores 215 may be non-catalytic (i.e., pyrolytic). The method described herein which uses the controlled formation of nanopores 215 on a catalyst support surface is sometimes called the “template method” of graphitic nanofilament growth.

It is to be understood that the alignment methods shown in FIGS. 2D-2F and described herein are applicable to graphitic nanofilaments in general and not just the base-growth nanotubes 200A which are shown for illustrative purposes. Additionally, nanofilament alignment may not be required in some applications and the nanofilaments may be formed so they are “non-aligned” on the catalyst support 205. As defined herein, “non-aligned” nanofilaments have nanofilament axes 216 which are randomly oriented with respect to each other and the support surface 206 of the catalyst support 205.

Host Substrates

Graphitic nanofilaments may be functionalized by using CVD growth methods to form the graphitic nanofilaments on various types of substrates to create different types of composite materials. The substrate type may be selected based on the desired application for the composite material.

FIG. 3A is a schematic top view of a host substrate 300 according to one embodiment described herein. The host substrate 300 is a continuous substrate of flexible material having an extended length, such as a fiber, tape, sheet, or web, for example. The sheet or web may comprise a fabric of woven fibers, a fiber composite, one or more layers of continuous material (e.g., polymeric or metallic sheet), or a combination thereof. The host substrate 300 may be mounted between supply and take-up reels, rollers, or other suitable supports. As shown in FIG. 3A, the thickness of the host substrate 300 is into the page of the drawing. The host material 300 may be formed from a material, such as polyimide, Kapton, glass containing materials, or composite materials comprising copper (Cu), aluminum (Al), nickel (Ni), and/or stainless steel foils. In one embodiment, the host material 300 may comprise materials which include but are not limited to carbon, carbon-containing compounds, carbides, carbon nanotubes, carbon nanofibers, silicas, aluminum oxides, lead zirconium titanate, glasses, ceramics, polymers, aramid, aromatic polyamides, polyethylenes, polyamides, nylons, acrylics, rayons, cellulosics, metals, metal alloys, semiconductors, superconductors, optical fibers, wires, or combinations thereof. In one embodiment, the host material has a thickness between about 3 μm and about 100 μm. In one embodiment, the host material 300 is adapted for use in a lithium ion battery application and has a thickness between about 3 microns (μm) and about 50 μm.

The host substrate 300 provides one or more surfaces upon which graphitic nanofilaments may be formed. In one embodiment, the host substrate 300 comprises the catalyst support 205. In another embodiment, the host substrate 300 comprises one or more surfaces upon which graphitic nanofilaments may be formed using non-catalytic CVD growth methods.

The host substrate 300 has one or more formation areas 302 which comprise areas in which graphitic nanofilaments are to be grown or formed. The formation areas 302 may comprise catalyst materials described herein for the catalyst particles 202, pores (e.g., nanopores 215), treated areas, or other materials and features which facilitate and help control graphitic nanofilament growth. In one embodiment, the substrate areas which lie outside the formation areas 302 are treated to inhibit or prevent graphitic nanofilament growth. In one embodiment, the formation areas 302 comprise the buffer layer 213 and/or the catalyst film 210.

The formation areas 302 are disposed on one or more surfaces of the host substrate 300. The one or more surfaces may include top, bottom, front, back, and side surfaces, for example, of the host substrate 300. The one or more surfaces may also be curved, such as for a cylindrically-shaped host substrate 300. In one embodiment, the formation areas 302 are disposed on a top surface 304 of the host substrate 300. The formation areas 302 may have any size and shape (rectangular is shown), and such shapes may include but are not limited to lines, dots, rectangles, polygons, and circles. The formation areas 302 may also be disposed in any pattern, such as an array (see FIG. 3B), for example. In one embodiment, the formation areas 302 completely cover one or more surfaces of the host substrate 300.

The formation areas 302 may be patterned onto the host substrate 300 using various patterning techniques, such as masking, lithography and etching, although other techniques may be contemplated, such as anodization. The patterning techniques may also be adapted to enable selective surface treatments and/or the selective deposition of materials, such as catalysts. For example, in a selective wetting technique, the host substrate 300 may be patterned to form hydrophobic and hydrophilic regions, and the catalyst material (which may be in solution) may be suitably adapted for selective deposition onto the hydrophobic or hydrophilic regions. In one example, the formation areas 302 and catalyst material are treated to be hydrophilic while the remaining top surface 304 is treated to be hydrophobic, thus enabling selective deposition of the catalyst material within the formation areas 302. The treatment may include depositing a treating material on various regions of the top surface 304 by masking, ink jet printing, screen printing or other similar technique and then allow the treating material to react with and modify the treated surfaces. The treating material that can be used to modify the host substrate 300 surface will vary by substrate material. In some cases, a fluorinated acid, fluorinated solvent, solvents, or other similar material may be used.

FIG. 3B is a schematic top view of a host substrate according to another embodiment described herein. The host substrate 300 is a discrete substrate having a finite size, such as a panel, metal foil, polymeric and metal foils, or wafer, for example. The host substrate 300 may comprise a rigid, semi-rigid, or flexible material which is mounted on one or more suitable supports. The host substrate 300 has one or more formation areas 302 as described herein. The formation areas 302 may be patterned in an array on one or more surfaces of the host substrate 300. For example, a 3×3 array (shown) of formation areas 302 may be disposed on the top surface 304.

Generally, the host substrates 300 shown in FIGS. 3A and 3B and described herein may be any size, shape, or structural form, and the forms may include but are not limited to plates, wafers, panels, sheets, webs, weaves, rods, bars, tubes, fibers, wires, tapes, metal foils, polymeric and metal foils, and ribbons. The host substrate 300 may also comprise materials which include but are not limited to metals, metal alloys, semiconductors, glasses, ceramics, optical fibers, polymers, fabrics, carbon fibers, silica, and aluminum oxide.

CVD Nanofilament Growth Apparatus

Graphitic nanofilaments may be formed on the host substrate 300 using CVD techniques which include but are not limited to atmospheric pressure CVD (APCVD), low pressure CVD (LPCVD), high pressure CVD (HPCVD), plasma enhanced CVD (PECVD), laser-enhanced CVD, thermal CVD, metal-organic CVD (MOCVD), and hot filament CVD. The CVD techniques used for graphitic nanofilament growth may be performed using various types of CVD deposition apparatuses known in the art and which include but are not limited to tube reactors (e.g., tube furnaces), showerhead reactors, linear injection reactors, hot-filament reactors, high pressure reactors, plasma reactors, and high-density plasma reactors. The CVD technique chosen for graphitic nanofilament growth may depend, in part, upon the desired growth parameters. For example, PECVD may be used to enable the dissociation of hydrocarbon gases at lower temperatures and facilitate the alignment of graphitic nanofilaments during growth.

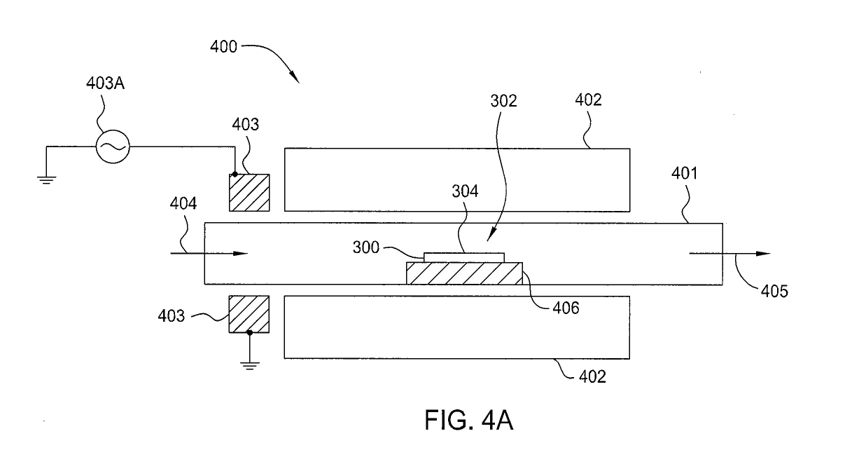

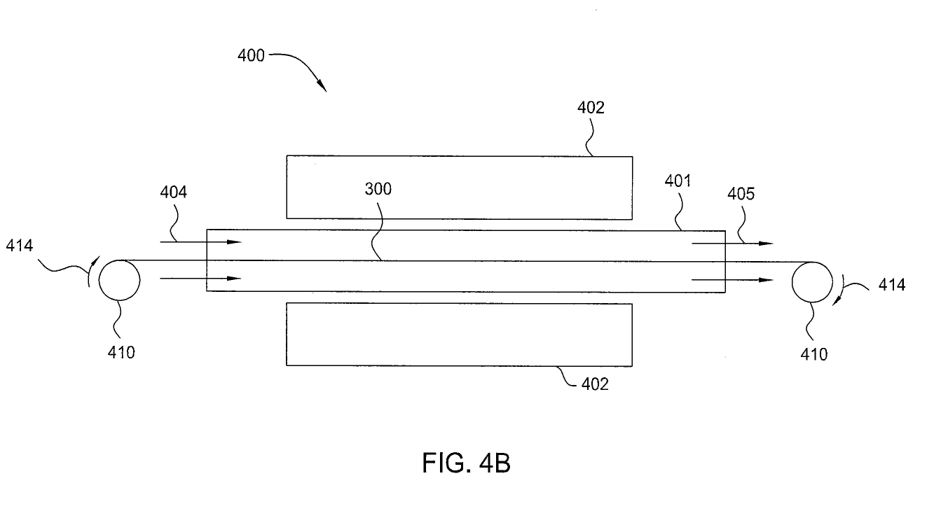

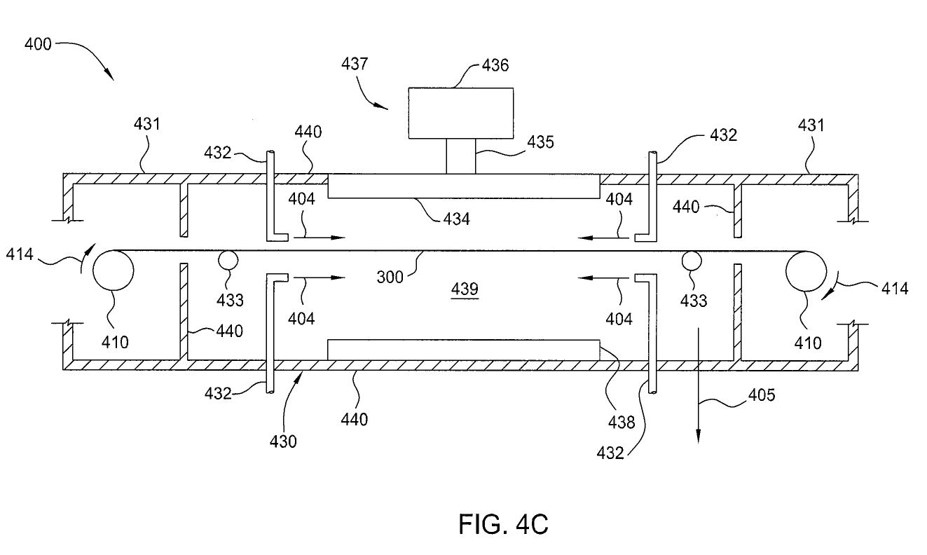

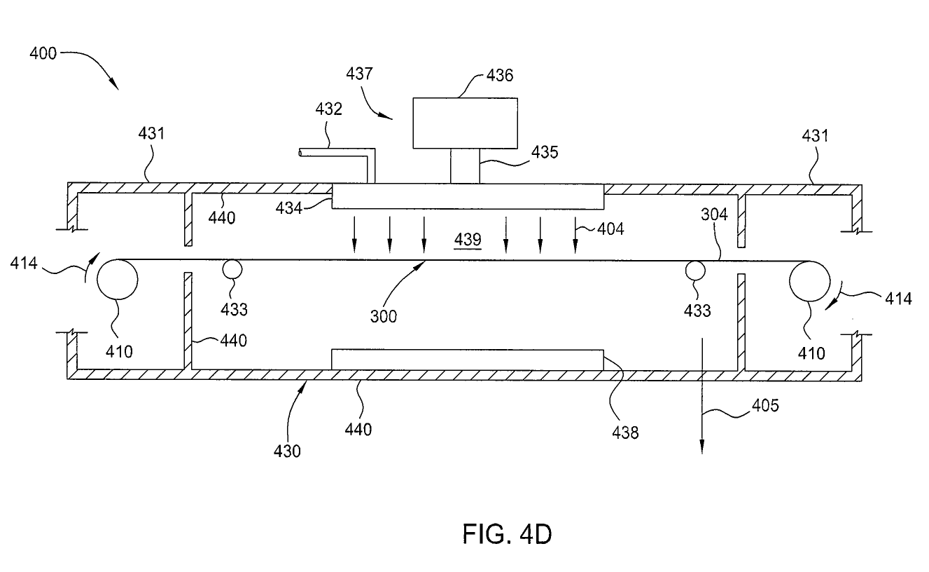

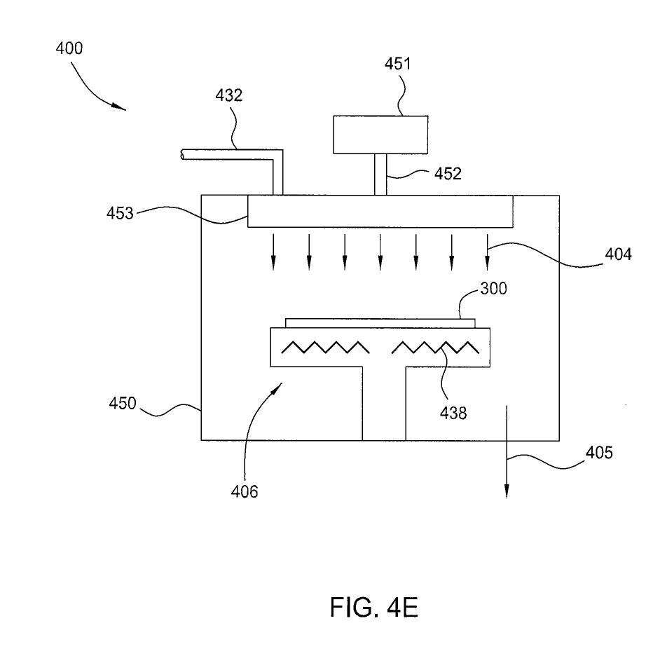

FIG. 4A is a simplified schematic view of an apparatus for growing graphitic nanofilaments on a host substrate 300 according to one embodiment described herein. A nanofilament growth apparatus 400 comprises a tube furnace having a reactor tube 401, one or more heating elements 402 disposed around the reactor tube 401, and a substrate support 406. The heating elements 402 may be adapted to form different temperature zones along the length of the reactor tube 401. The reactor tube 401 comprises a refractory material (e.g., quartz), and the heating elements 402 may comprise resistive heaters, induction coils, lamps, or other means for heating the host substrate 300 which is disposed on the substrate support 406 within the reactor tube 401. The substrate support 406 may be a susceptor which comprises a material (e.g., graphite) which allows inductive heating of the substrate support 406. The reactor tube 401 and substrate support 406 may be suitably sized to process host substrates 300 having different sizes and shapes.

The tube furnace may be suitably adapted to include a plasma source 403 which may be disposed at any location along the length of the reactor tube 401. The plasma source 403 may comprise electrodes, induction coils, waveguides (e.g., microwave or RF waveguide), power sources and other means for producing a plasma within the reactor tube 401.

A process gas 404 enters one end of the reactor tube 401 and flows through the tube and over the exposed surfaces of the host substrate 300. The tube furnace is coupled to and in fluid communication with a vacuum pump (not shown) which maintains gas flow through the reactor tube 401 and which evacuates exhaust gas 405 from an opposite end of the tube. The vacuum pump can be controlled so that the pressure inside the reactor tube 401 may be adjusted.

The process gas 404 may comprise a carbon source gas, an auxiliary gas or gases (e.g., carrier gas, inert gas, reducing gas, dilution gas), and one or more catalyst-containing materials, such as a catalyst precursor, for example. In one embodiment, the process gas 404 comprises a carbon source gas and an auxiliary gas. The tube furnace may be adapted so that each of the gases and catalyst-containing materials which comprise the process gas 404 may be injected sequentially or simultaneously into the reactor tube 401, and each gas or catalyst may be injected at different locations along the reactor tube 401, and each injection location may be disposed in a different temperature zone along the tube. The tube furnace may also be adapted to inject liquid catalyst precursors into the reactor tube 401 using atomizers, syringe pumps, or other means.

In one embodiment, an inert gas (e.g., argon) is first flowed into the reactor tube 401 to remove air and create an inert atmosphere in the tube. The inert atmosphere in the tube is then heated to the graphitic nanofilament growth temperature. A reducing gas, such as hydrogen, may also be added to the inert gas flow during heating. When the growth temperature is reached, the carbon source gas is flowed into the reactor tube 401. The carbon source gas, auxiliary gas, catalysts, growth temperature, and other growth parameters may be selected to grow the desired graphitic nanofilament structures.

In one embodiment, as shown in FIG. 4A, the carbon source gas reacts with catalyst material in the formation areas 302 (see FIGS. 3A and 3B) to form graphitic nanofilaments on the host substrate 300. The growth of the nanofilaments may be facilitated by the plasma source 403 which assists in the dissociation of the process gas 404. The plasma source 403 may also be positioned and aligned so that it can provide a desirably oriented electric field near the surface of the host substrate 300 to help align the graphitic nanofilaments. The plasma source 403 may be a capacitively coupled source (i.e., anodic member and cathodic member) or an inductively coupled source (i.e., coil) that is coupled to an RF power source assembly 403A having RF power supply and conventional matching circuit. In one embodiment, the tube furnace and host substrate 300 are suitably adapted so that the graphitic nanofilaments are non-aligned.

The reactor tube 401 and host substrate support 406 may be suitably adapted so that the orientation of the host substrate 300 relative to the flow of the process gas 404 can be adjusted. In one embodiment, the top surface 304 of the host substrate 300 is approximately parallel (as shown in FIG. 4A) to the flow direction (indicated by arrow) of the process gas 404. In another embodiment, the top surface 304 of the host substrate 300 is approximately perpendicular to the flow direction of the process gas 404.

In another embodiment, the tube furnace may be adapted to form graphitic nanofilaments using the floating catalyst method. One or more catalyst precursors may be injected into the reactor tube 401 and then decomposed and/or reduced by heat or a reducing gas to form catalyst nanoparticles which react with the carbon source gas to form graphitic nanofilaments on the host substrate 300. One or more surfaces of the host substrate 300 may be patterned and suitably treated so that graphitic nanofilaments are selectively formed within the formation areas 302 using the floating catalyst method.

FIG. 4B is a simplified schematic view of another embodiment of the apparatus shown in FIG. 4A. The nanofilament growth apparatus 400 comprises a tube furnace which is suitably adapted for graphitic nanofilament growth on a host substrate 300 which comprises a continuous substrate, such as a fiber, tape, sheet, metal foil, polymer and metal foil composite, or web, for example, although other types of continuous substrates may be contemplated. The host substrate 300 is supported by at least two primary supports 410. The primary support 410 may comprise a roller, wheel, supply reel, or take-up reel. The primary support 410 is adapted to rotate in a rotation direction 414 so that the host substrate 300 may move through the reactor tube 401 and graphitic nanofilaments can be grown along the length of the host substrate 300. One or more of the primary supports 410 may be coupled to the host substrate 300 for moving the host substrate 300 and positioning portions thereof, and one or more of the primary supports 410 may be coupled to a suitable drive, motor, or other actuator (not shown) which causes rotation of the primary support 410. The graphitic nanofilaments may be grown on one or more surfaces or sides of the host substrate 300. The growth time (or residence time) may be controlled by adjusting the speed of the host substrate 300 as it moves through the reactor tube 401. The motion of the host substrate 300 through the reactor tube 401 may be continuous or intermittent during the growth process.

FIG. 4C is a simplified schematic view of another apparatus for growing graphitic nanofilaments on a host substrate 300 according to one embodiment described herein. The nanofilament growth apparatus 400 comprises a CVD process chamber 430 for nanofilament growth. The process chamber 430 comprises chamber walls 440 which enclose a processing region 439 for growing graphitic nanofilaments on the host substrate 300. The nanofilament growth apparatus 400 may further comprise one or more buffer chambers 431 coupled to the process chamber 430, and the buffer chambers 431 may be coupled to other types of chambers (not shown) for processing or transferring the host substrate 300.

In one embodiment, the process chamber 430 and the buffer chambers 431 comprise vacuum chambers and the buffer chambers 431 may operate at pressures greater than the pressure of process chamber 430. A vacuum pumping system (not shown) is coupled to and in fluid communication with the process chamber 430 and/or buffer chambers 431. The vacuum pumping system is adapted to remove exhaust gas 405 (FIG. 4B) from the process chamber 430, and the vacuum system may be adjusted to control the pressures in the process chamber 430 and buffer chambers 431. In another embodiment, the process chamber 430 and the buffer chambers 431 are adapted for processing at atmospheric pressures.

In one embodiment, the nanofilament growth apparatus 400 is adapted for processing a host substrate 300 which comprises a continuous substrate such as a fiber, sheet, metal foil, polymeric and metal foil composite, or web, for example, as shown in FIG. 4C. In another embodiment, the nanofilament growth apparatus 400 is adapted for processing a host substrate 300 which comprises a discrete substrate such as a panel, for example, although other types of discrete substrate may be contemplated.

The nanofilament growth apparatus 400 comprises one or more primary supports 410 and may also comprise one or more secondary supports 433 for supporting and moving the host substrate 300. The secondary supports 433 comprise rollers, wheels, or other suitable means for supporting and guiding the host substrate 300 as it moves through the process chamber 430. The primary supports 410 may be disposed within the process chamber 430 or one or more buffer chambers 431 (as shown). In another embodiment, the primary supports 410 and secondary supports 433 are adapted to move through the process chamber 430 to allow the positioning and processing of the host substrate 300 in either a stationary or continuously moving processing mode.

The process chamber 430 includes one or more gas conduits 432 and one or more heating elements 438 disposed about the host substrate 300 in the processing region 439. The gas conduits 432 supply process gas 404 to the process chamber 430, and the gas conduits 432 may be disposed within the process chamber 430 to facilitate the formation of graphitic nanofilaments on one or more surfaces of the host substrate 300, such as the top and bottom surfaces of a sheet, metal foil, polymeric and metal foil composites, web, or panel, for example.

The heating elements 438 may comprise lamps, resistive heating elements, induction coils, or other suitable means for heating the host substrate 300. Additionally, the means for heating the host substrate 300 may be adapted for electrically conductive substrates and catalysts. In one embodiment, the heating elements 438 comprise induction coils which are used to enable inductive heating of electrically conductive host substrates 300 and/or metallic catalyst materials deposited thereon. In another embodiment, the nanofilament growth apparatus 400 is adapted to pass electrical currents through electrically conductive host substrates 300 (e.g., conductive wires, fibers, foils, sheets) to heat the host substrates 300 and facilitate nanofilament growth.

The process chamber 430 may also include one or more plasma sources 437 disposed about the host substrate 300 for PECVD growth of graphitic nanofilaments. The plasma source 437 comprises a first element 434, a second element 435, and a third element 436. In one embodiment, the first element 434 comprises an electrode which is electrically isolated from a counter-electrode which may comprise the host substrate 300, chamber walls 440, or other elements within the process chamber 430. The second element 435 electrically couples the first element 434 or electrode to the third element 436 which comprises an energy source (e.g., radio frequency (RF) generator) for plasma generation. The plasma source 437 facilitates the growth of graphitic nanofilaments by forming a plasma from the process gas 404. The plasma source 437 may also be adapted to facilitate alignment of the nanofilaments on the host substrate 300, as described herein.

In another embodiment, the first element 434 comprises one or more induction coils electrically coupled by the second element 435 to the third element 436 which comprises an energy source (e.g., RF generator) for driving the one or more induction coils. The one or more induction coils may be located within (as shown) or outside the chamber walls 440 so that the coils may form a plasma from the process gas 404.

In yet another embodiment, the first element 434 comprises a window which is transparent to radiation (e.g., microwave, radio frequency), the second element 435 comprises a waveguide for the radiation, and the third element 436 comprises an energy source for radiation generation (e.g., radio frequency or microwave generator). Radiation is produced by the energy source and delivered through the waveguide and through the window into the process chamber 430 where the radiation forms a plasma from the process gas 404.

FIG. 4D is a simplified schematic view of another embodiment for the apparatus shown in FIG. 4C. The one or more gas conduits 432 are coupled to and in fluid communication with the first element 434 which comprises a showerhead which also functions as an electrode for generating a capacitively coupled plasma. A counter-electrode may comprise the host substrate 300, chamber walls 440, or other elements within the process chamber 430. The second element 435 comprises an electrical coupling between the first element 434 or showerhead and the third element 436 which comprises an energy source (e.g., RF generator) for plasma generation. The showerhead injects process gas 404 into the process chamber 430 so that the gas is distributed over a portion of the host substrate 300, and a plasma is formed from the process gas 404 in the processing region 439. In one embodiment, the processing region 439 is located between the showerhead and the host substrate 300 and graphitic nanofilaments are formed only on the top surface 304 of the host substrate 300.

The embodiments described herein for FIGS. 4C and 4D may also be combined, substituted, or interchanged. For example, one or more plasma sources 437 may be replaced with additional heating elements 438, or one or more heating elements 438 may be replaced with various embodiments of plasma sources 437, and other embodiment combinations may be contemplated for different applications.

FIG. 4E is a simplified schematic view of an apparatus for growing graphitic nanofilaments on a host substrate 300 according to another embodiment described herein. The nanofilament growth apparatus 400 comprises a PECVD process chamber 450. The process chamber 450 is adapted for processing host substrates 300 which are discrete substrates, such as wafers or panels, for example.

The process chamber 450 comprises a substrate support 406 for supporting the host substrate 300 and a gas showerhead 453 for injecting process gas 404 into the process chamber 450. The process gas 404 is delivered to the gas showerhead 453 by the gas conduit 432 which is coupled to and in fluid communication with the gas showerhead 453. One or more heating elements 438 are embedded within the substrate support 406 to facilitate nanofilament growth. The heating elements 438 may comprise resistive heating elements, induction coils, or other heating means A vacuum pumping system (not shown) is coupled to and in fluid communication with the process chamber 450 so that exhaust gases 405 may be removed from the chamber and the chamber pressure may be adjusted.

The gas showerhead 453 is electrically coupled to a plasma energy source 451 by an electrical connector 452. The plasma energy source 451 may comprise a radio frequency power source, a DC power source, or other means for generating a plasma. The gas showerhead 453 functions as an electrode for generating a capacitively-coupled plasma. The gas showerhead 453 is electrically isolated from a counter-electrode which may comprise the substrate support 406, walls of the process chamber 450, or other elements of the of the process chamber 450. The gas showerhead 453 injects process gas 404 into the process chamber 450 and the plasma energy source 451 is energized so that a plasma is formed from the process gas 404.

The embodiments shown in FIGS. 4A-4E and described herein may be combined to form other embodiments for the nanofilament growth apparatus 400. Additionally, the nanofilament growth apparatuses 400 described herein are not meant to be limiting and various types of CVD apparatuses known in the art may be adapted to grow graphitic nanofilaments on the host substrate 300.

After the graphitic nanofilaments have been formed on the host substrate 300 using the nanofilament growth apparatus 400, the nanofilaments may be metallized to form the desired composite material.

Nanofilament Composite Material

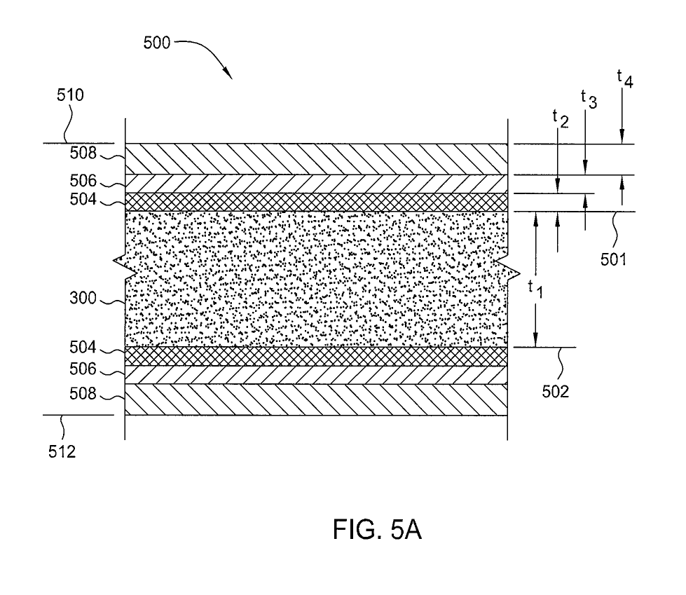

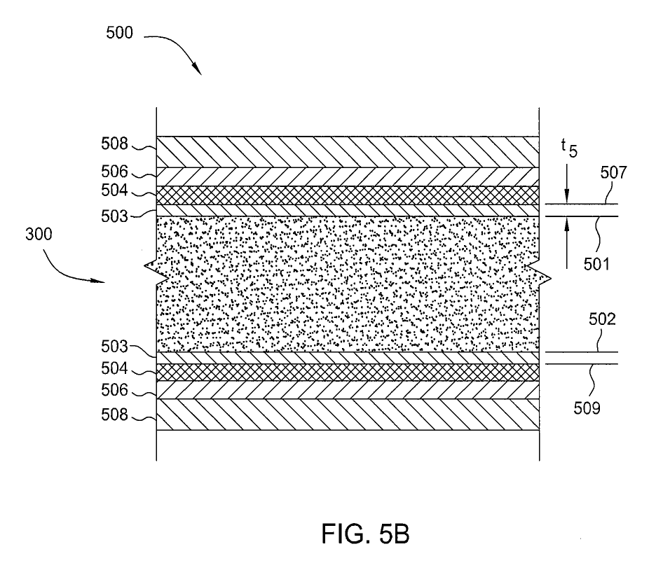

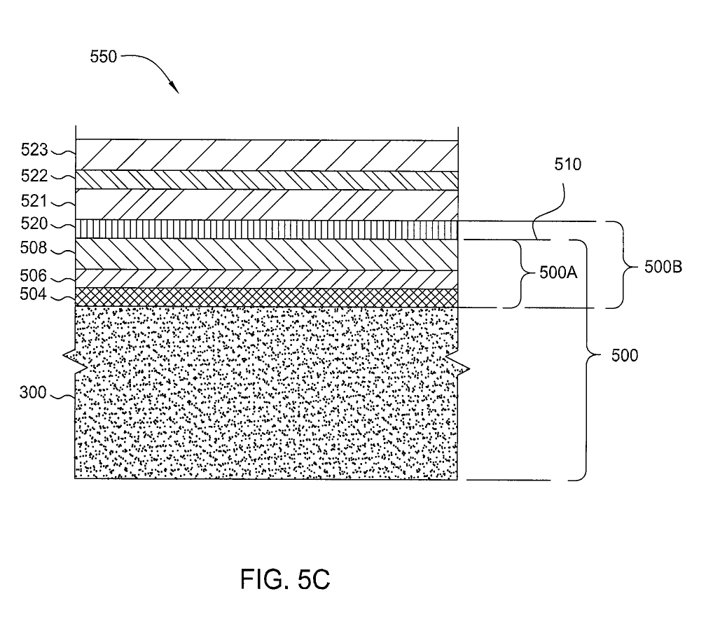

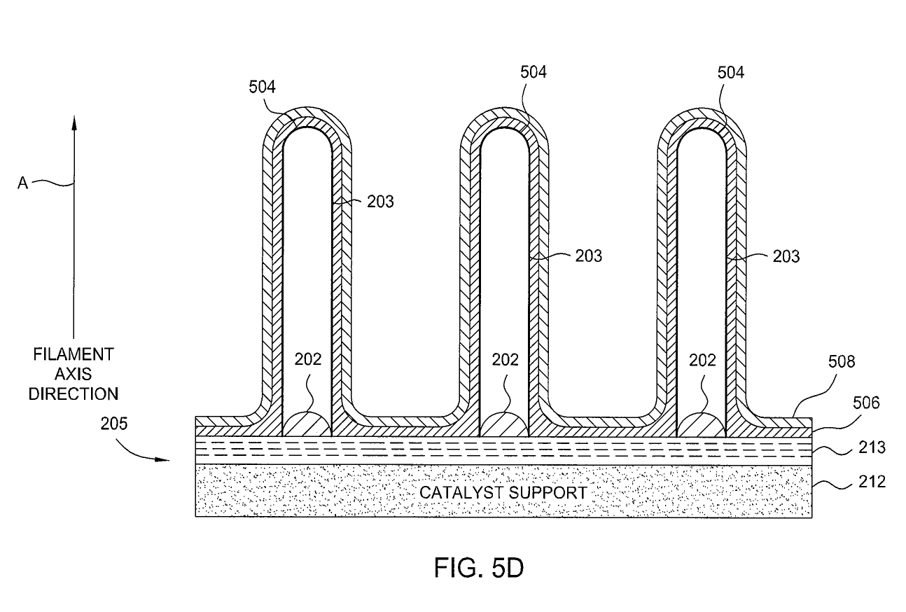

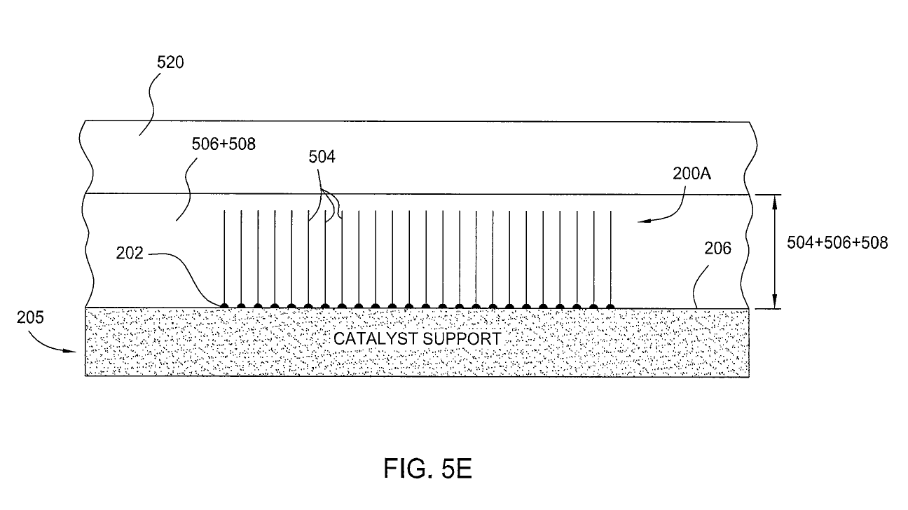

FIG. 5A is a simplified cross-sectional view of a nanofilament composite material 500 comprising metallized graphitic nanofilaments on a host substrate 300 according to one embodiment described herein. The nanofilament composite material 500 comprises a host substrate 300 which comprises a first surface 501 and a second surface 502. The first surface 501 and the second surface 502 may comprise two separate surfaces (e.g., top surface and bottom surface) of the host substrate 300. In another embodiment, the first surface 501 and the second surface 502 comprise a single outer surface (e.g., cylindrical surface) of the host substrate 300. Each of the first surface 501 and the second surface 502 comprise one or more formation areas 302 (see FIGS. 3A-3B) which may comprise deposited materials and/or treated surfaces which facilitate and help control graphitic nanofilament growth as described herein.

On each of the first surface 501 and the second surface 502, the nanofilament composite material 500 further comprises a nanofilament layer 504, an initiation-adhesion layer 506 formed over the nanofilament layer 504, and a metallic layer 508 formed on the initiation-adhesion layer 506. In another embodiment, only the first surface 501 is covered with the aforementioned layers. A first metallic surface 510 and a second metallic surface 512 of the metallic layers 508 may receive additional material layers thereon to adapt the nanofilament composite material 500 for a particular application.

The nanofilament layer 504 comprises graphitic nanofilaments (i.e., carbon nanotubes and/or nanofibers) which are formed on the host substrate 300. The nanofilament layer 504 may also comprise materials (e.g., species of metals) which are intercalated with the graphitic nanofilaments.

The initiation-adhesion layer 506 comprises one or more layers of materials which facilitate the deposition and adhesion of the metallic layer 508. The initiation-adhesion layer 506 may comprise a nucleation, seed and/or initiation layer which prepares the nanofilament layer 504 for the deposition of a metallic material. In one embodiment, the initiation-adhesion layer 506 comprises a seed or nucleation layer which comprises materials which include but are not limited to copper, lithium, tin, aluminum, bismuth, antimony, nickel, titanium, vanadium, chromium, manganese, iron, cobalt, silver, gold, zinc, and alloys and oxides thereof. In another embodiment, the initiation-adhesion layer 506 comprises an initiation layer which comprises one or more catalytic materials which may initiate an electroless plating process. The catalytic materials may be deposited using sensitizing and activating solutions. In one embodiment, the initiation-adhesion layer 506 comprises catalytic materials which include but are not limited to palladium, tin, platinum, gold, rhodium, ruthenium, magnesium, osmium, iridium, iron, copper, cobalt, lead, mercury, nickel, aluminum, titanium, and carbon.

The metallic layer 508 comprises one or more layers of metal or metal alloy. The metallic layer 508 may comprise materials which include but are not limited to copper, lithium, tin, aluminum, bismuth, antimony, nickel, titanium, vanadium, chromium, manganese, iron, cobalt, silver, gold, zinc, magnesium, molybdenum, platinum, lead, alloys thereof, oxides thereof, and combinations thereof. In one embodiment, the initiation-adhesion layer 506 and metallic layer 508 may be made sufficiently thin and/or porous to allow the passage of metal ions (e.g., lithium, sodium, potassium) through each layer.

Referring to FIG. 5A, the host substrate 300 has a thickness “t1” which may have a wide range of values depending upon the type of host substrate 300 used for the nanofilament composite material 500. In one embodiment, the thickness “t1” ranges from a few hundred micrometers to about 10 millimeters. In one embodiment, the thickness “t1” range is between about 50 and about 100 μm. The nanofilament layer 504 has a thickness “t2” which can be up to several tens of micrometers or higher. The initiation-adhesion layer 506 has a thickness “t3” and the metallic layer 508 has a thickness “t4.” In one embodiment, each thickness “t3” and “t4” ranges from about 0.01 micrometers to about 25 micrometers. In another embodiment, each thickness “t3” and “t4” ranges from a few angstroms to a few micrometers. In one embodiment, the initiation-adhesion layer 506 comprises a seed layer and has a thickness “t3” which ranges from about 10 angstroms to about 2,500 angstroms.

FIG. 5B is another embodiment described herein of the nanofilament composite material shown in FIG. 5A. The nanofilament composite material 500 comprises one or more supplementary layers 503 wherein each layer comprises one or more treatment layers and/or layers of deposited material (e.g., catalytic material). The supplementary layer(s) 503 may be disposed between any two layers of the nanofilament composite material 500, or on the metallic layer 508. In one embodiment, the supplementary layer 503 has a thickness “t5” which ranges from a few nanometers to a few tens of micrometers.

The supplementary layer 503 may comprise various supplementary materials. In one embodiment, the supplementary materials comprise catalysts or other materials which facilitate and help control the growth of graphitic nanofilaments. In one embodiment, the host substrate 300 comprises supplementary layers 503 formed on the first surface 501 and the second surface 502, and the supplementary layers 503 comprise a first surface 507 and a second surface 509 having nanofilament layers 504 formed thereon. Each of the first surface 507 and the second surface 509 comprise one or more formation areas 302. In one embodiment, the supplementary layer 503 may comprise the buffer layer 213, catalyst materials described above relating to the catalyst particles 202, nanopores 215, an oxide layer, combinations thereof, or other materials and features which are used to form the formation areas 302. In one example, the oxide layer may comprise various types of oxides which may be formed by exposing the first surface 501 and the second surface 502 to air or by oxidizing treatments of said surfaces.

In another embodiment, the supplementary layer 503 comprises supplementary materials and/or features which inhibit or prevent the growth of graphitic nanofilaments, and such materials or features may be disposed between or outside the formation areas 302. In one embodiment, the supplementary layer 503 comprises two or more layers wherein some layers facilitate and promote graphitic nanofilament growth and other layers inhibit or prevent nanofilament growth, and each layer may be patterned to form the formation areas 302.

In yet another embodiment, the supplementary layer 503 comprises supplementary materials which may enhance or modify properties of the nanofilament composite material 500, and such materials may include forms of carbon, such as diamond, diamond-like carbon (DLC), and fluorinated carbon, or other materials such as silicates, metal oxides, metal fluorides, ceramics, and polymers, for example. In one embodiment, the supplementary layer 503 is disposed between the nanofilament layer 504 and the initiation-adhesion layer 506. In one embodiment, the initiation-adhesion layer 506 and/or metallic layer 508 comprise supplementary materials which include but are not limited to diamond, diamond-like carbon (DLC), fluorinated carbon, silicates, metal oxides, metal fluorides, ceramics, and polymers.

Electrochemical in Lithium Battery

The nanofilament composite material 500 may be used for various applications. In one embodiment, the nanofilament composite material 500 is used in a device for electrochemical energy storage. FIG. 5C is a simplified cross-sectional view of an electrochemical storage device 550 which includes the nanofilament composite material 500 shown in FIG. 5A, according to one embodiment described herein. The electrochemical storage device 550 comprises a battery which is formed by depositing additional material layers on a surface of the nanofilament composite material 500. In one configuration, the nanofilament composite material 500 in the electrochemical storage device 550 comprises a porous material region 500A (FIG. 5C), which generally contains the formed nanofilament layer 504, initiation-adhesion layer 506 and/or metallic layer 508. The nanofilament composite material 500 forms an electrode (or current collector) in the electrochemical storage device 550. A first electrode layer 520 is deposited on the first metallic surface 510 of the porous material region 500A, an electrolyte layer 521 is deposited on the first electrode layer 520, a second electrode layer 522 is deposited on the electrolyte layer 521, and a metallic layer 523 is deposited on the second electrode layer 522. The electrolyte layer 521 comprises a solid electrolyte material, or polymeric electrolyte material, which is used as an ionic conductor and separator material. The conductive materials formed in the porous material region 500A on the host substrate 300, such as metallic layer 508, may function as an anodic current collector. The metallic layer 523 comprises a metal or metal alloy serving as a cathodic current collector. The first electrode layer 520 and porous material region 500A each may comprise an anodic material and functions as an anode, where first electrode layer 520 is formed so that it penetrates into the underlying materials found in the porous material region 500A to form a composite electrode layer 500B. In one embodiment, as shown in FIG. 5D, the porous material region 500A contains a nanofilament layer 504 that is conformally covered by the initiation-adhesion layer 506 and metallic layer 508, and then by the first electrode layer 520. In another embodiment, as shown in FIG. 5E, the porous material region 500A contains a nanofilament layer 504 that is non-conformally covered by the initiation-adhesion layer 506 and metallic layer 508, and then by the first electrode layer 520. In the configuration illustrated in FIG. 5E, the regions surrounding the nanofilament layer 504 are filled with the initiation-adhesion layer 506 and metallic layer 508 materials, which then may then have the first electrode layer 520 disposed thereon. It is believed that the use of the nanofilament layer 504 in the electrode structure will provide a high electrical and ionic conductivity to the electrode structure, due to the use of the carbon nano-tubes. The second electrode layer 522 comprises a cathodic material and functions as a cathode. In one embodiment, the first electrode layer 520 is graphite, tin (Sn), and/or silicon (Si). In one embodiment, the second electrode layer 522 is a material selected from the group consisting of LiCoO, LiCoNiO, LiFePO, LiCoMnO, LiNiMnCo and/or LiCoAlO. In another embodiment, the first electrode layer 520 comprises a cathodic material and the second electrode layer 522 comprises an anodic material. The metallic substrate 300 and metallic layer 523 may function as current collectors for the composite electrode layer 500B and the second electrode layer 522, respectively. An optional outer layer (not shown) which functions as a protectant and sealant may be deposited over the metallic layer 523. In another embodiment, the nanofilament composite material 500 shown in FIG. 5A is replaced by the nanofilament composite material 500 shown in FIG. 5B and described herein to form the electrochemical storage device 550. In one embodiment, an optional porous polyolefin material may be inserted between anode and cathode, such as in the middle of the electrolyte layer 521.

In another embodiment of the nanofilament composite material 500, a liquid electrolyte is disposed within and fills the nanofilament composite material 500 structure. The liquid electrolyte can thus be used to carry the generated current within a formed electrochemical device. The liquid electrolyte material may comprise lithium hexafluorophosphate (LiPF6), ethylene carbonate, and dimethyl carbonate.

Formation of the Nanofilament Composite Material

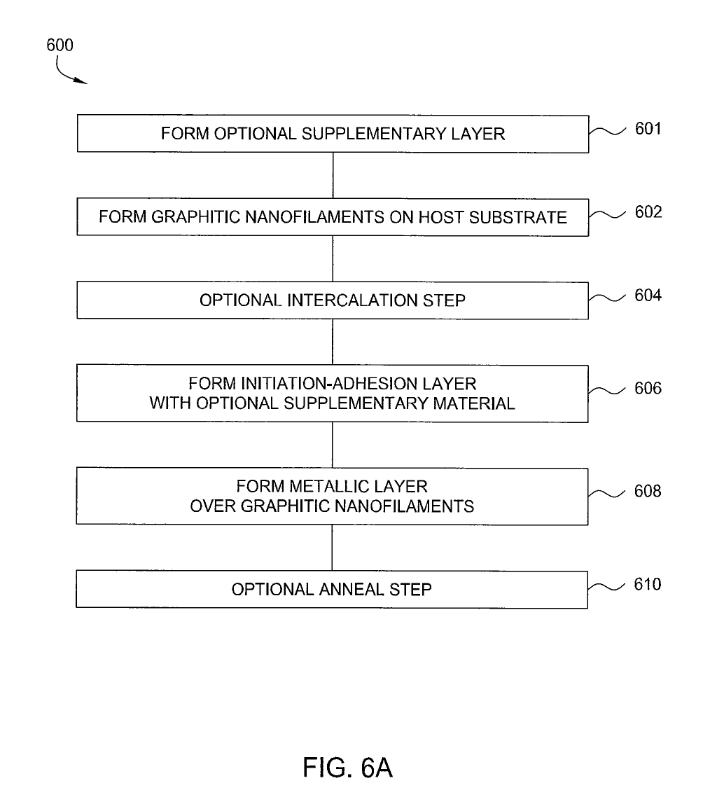

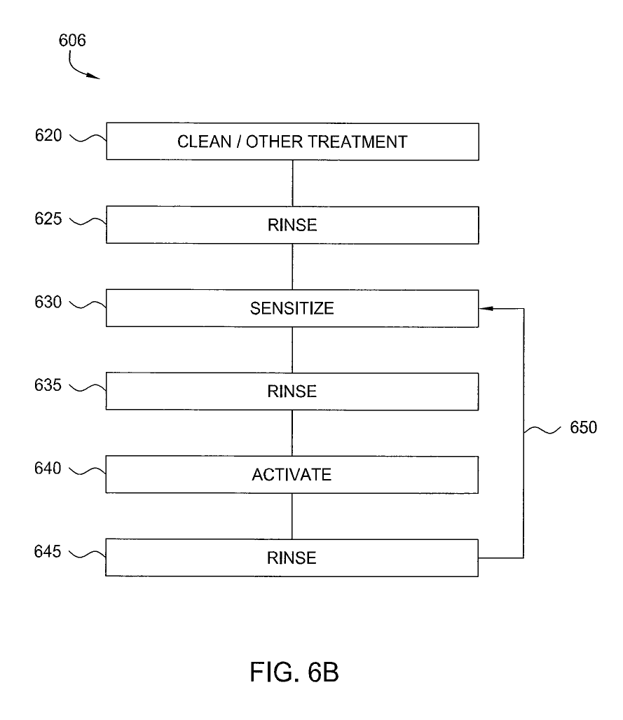

FIG. 6A illustrates a process for forming the nanofilament composite material 500 shown in FIGS. 5A and 5B according to one embodiment described herein. The process comprises a series of method steps 600 which start with an optional step 601 in which the supplementary layer 503 is formed on one or more surfaces of the host substrate 300. The supplementary layer 503 may be patterned using various patterning techniques which include but are not limited to masking, screen printing, ink jet printing, lithography, and etching. The patterned supplementary layer 503 may form the patterned formation areas 302 (see FIGS. 3A-3B). In another embodiment, the nanofilament composite material 500 comprises one or more supplementary layers 503, and the step 601 may be repeated after any one of the method steps 600.

The supplementary layer 503 may be formed by treating the one or surfaces of the host substrate 300 and/or by depositing supplementary materials thereon. The treatments may include but are not limited to heating, etching, irradiating, anodizing, and oxidizing. The supplementary materials may be deposited using wet or dry deposition techniques which include but are not limited to sputtering, chemical vapor deposition, plasma enhanced chemical vapor deposition, electrochemical deposition, electroless deposition, selective wetting, ion beam assisted sputtering, electrophoresis, and cathodic arc and laser ablation of carbon targets. The supplementary layer 503 may include copper, aluminum, titanium and nickel.

The step 601 may comprise multiple steps for forming the supplementary layer 503 which may comprise multiple treatment and deposition layers. For example, one or more surfaces of the host substrate 300 may be oxidized to form an oxide layer followed by depositing a first catalyst material to form a first catalyst layer on the oxide layer and then depositing a second catalyst material to form a second catalyst layer on the first catalyst layer. Alternate treatments, supplementary materials, and sequences of deposition and treatment may be contemplated for the supplementary layer 503.

Next, in a step 602, graphitic nanofilaments are formed on one or more surfaces of the host substrate 300 to produce nanofilament layers 504. In one embodiment, catalyst materials used to form graphitic nanofilaments are deposited on the host substrate 300 before the step 602. In another embodiment, catalyst materials are deposited on the host substrate 300 during the step 602, such as when using the floating catalyst method of graphitic nanofilament formation, for example. The graphitic nanofilaments may be formed using various CVD techniques described herein.

In an optional step, a step 604, the graphitic nanofilaments may be intercalated with species (e.g., ions) of metals, such as the alkali metals (e.g., lithium, sodium, potassium, rubidium, etc.), for example. The term “intercalation” may be defined as the reversible insertion of guest species (e.g., ions, atoms, molecules) into a solid host material without a major disruption or change of the host material. A host material (e.g., graphitic nanofilaments) which may be intercalated has the property which allows guest species (e.g., metal ions) to readily move in and out of the host material without the host material changing its phase.

The intercalation of the graphitic nanofilaments may be desirable when the nanofilament composite material 500 forms part of an energy storage device. The large surface areas of graphitic nanofilaments may be used to create porous electrodes with superior ion storage and reversibility capacities and such electrodes may be used in high performance energy storage devices such as rechargeable batteries (e.g., lithium-ion batteries). Reversible specific capacities for accepting lithium for single-walled carbon nanotubes have been reported by Zhou et al. (U.S. Pat. No. 6,422,450) at values of about 550 milliampere-hours per gram (mAh/g) and higher compared to a maximum (theoretical) reversible capacity of about 372 mAh/g for graphite.

The graphitic nanofilaments may be intercalated with metal ions using various electrochemical, chemical, or physical methods. In electrochemical methods the graphitic nanofilaments form an electrode in a cell which includes an electrolyte and a counter-electrode which acts as a source for the metal ion. The cell is then charged and the metal ions leave the counter-electrode and are inserted into the graphitic nanofilaments. Chemical methods include adding a metal salt (e.g., alkali metal salt) to a suitable solvent to form a solution containing the metal ions and then immersing the graphitic nanofilaments into the solution to intercalate the carbon nanofilaments with the metal ions. Alternately, physical transport methods (e.g., vapor diffusion) which expose the nanofilaments to a heated metal vapor may be used for some types of metal ions (e.g., lithium, potassium, sodium) to perform the intercalation. Other methods, however, may be contemplated for the intercalation of the graphitic nanofilaments.

In the next step, a step 606, the initiation-adhesion layer 506 is formed over the nanofilament layer 504. The step 606 comprises one or more steps which prepare the nanofilament layer 504 for the deposition of metallic materials thereon. The step 606 may comprise depositing materials, removing materials, and/or removing contamination, or cleaning, operations. For example, various treatments may be applied to the nanofilament layer 504 to remove catalyst particles 202 remaining in the graphitic nanofilaments. Such treatments may include applying solutions which contain acids (e.g., hydrochloric, sulfuric, nitric, etc.) to the nanofilaments or exposing the nanofilaments to plasmas.

The initiation-adhesion layer 506 may be deposited using deposition techniques which include but are not limited to sputtering, chemical vapor deposition, atomic layer deposition, electrochemical deposition, electroless deposition, and electrophoretic deposition. Various materials which may be deposited are described herein for the initiation-adhesion layer 506.

In one embodiment, the initiation-adhesion layer 506 comprises a seed or nucleation layer. In another embodiment, the initiation-adhesion layer 506 comprises an initiation layer which prepares the nanofilament layer 504 for electroless deposition of the metallic layer 508. The step 606 may comprise multiple steps such as cleaning, rinsing, sensitizing, and activating which are performed on the nanofilament layer 504 prior to the electroless deposition of a metal thereon.

Electroless deposition is a plating process which does not require an electrical current to drive the deposition process, and deposition of the plating metal is typically initiated by one or more catalytic materials. The surface to be plated may comprise the one or more catalytic materials or the catalytic materials may be deposited onto the surface during sensitizing and activating steps. The activating step is usually preceded by a sensitizing step which treats the plating surface to promote adhesion of the catalytic material and plating metal to the surface to be plated. The catalytic material is covered by the plating metal during electroless deposition but the plating metal also acts as a catalyst which further drives the metal deposition. Thus, electroless deposition is sometimes referred to as an autocatalytic deposition process. Since the plating metal acts as a catalyst, the metal thickness may be controlled by the exposure time of the plating surface to the electroless plating solution.

The electroless deposition process includes the immersion of the surface to be plated in one or more electroless plating solutions or baths. The electroless plating solutions are typically aqueous solutions, which include a metal salt containing the plating metal, one or more reducing agents, complexing agents, pH adjusters, and other additives to control solution stability, film properties, and metal deposition rate. In one embodiment, the step 606 comprises the immersion of the nanofilament layer 504 into one or more solutions which include but are not limited to sensitizing solutions, activating solutions, plating solutions, etching solutions, cleaning solutions, rinsing solutions, or other surface treating solutions and combinations thereof which form the initiation-adhesion layer 506.

FIG. 6B illustrates a process for the step 606 shown in FIG. 6A according to one embodiment described herein. The step 606 comprises multiple steps which comprise the sequential immersion of the nanofilament layer 504 into a series of solutions. Starting with a step 620, the nanofilament layer 504 is cleaned by immersing the layer in a cleaning solution. In another embodiment, the step 620 comprises dry cleaning treatments (e.g., plasma etch cleaning). The step 620 may also comprise other types of treatments, such as removal of catalyst nanoparticles from the nanofilaments, for example. Next, in a step 625, the nanofilament layer 504 is rinsed in a rinsing solution (e.g., de-ionized water), followed by immersing the layer in a sensitizing solution in a step 630, followed by rinsing in a step 635. In a step 640, the nanofilament layer 504 is immersed in an activating solution and then, in a step 645, the layer is again rinsed in a rinsing solution.

In another embodiment, the steps 630, 635, and 640 comprise a single step which comprises immersing the nanofilament layer 504 into a single sensitizing-activating solution. In yet another embodiment, the step 606 further comprises two additional steps which follow the step 645, namely, an electroless metal plating step followed by another rinsing step.

In one embodiment, the step 606 comprises a sequence of steps which define a process cycle 650 which may be repeated. For example, the nanofilament layer 504 is immersed in a sensitizing solution in the step 630 for a first duration, rinsed in the step 635, and then immersed in an activating solution in the step 640 for a second duration. The nanofilament layer 504 is then rinsed in the step 645 and the process cycle 650 is repeated, starting again with step 630. The process cycle 650 comprises the steps 630, 635, 640, and 645, and the cycle may be repeated any number of times. In one embodiment, the process cycle 650 is repeated once. In another embodiment, the first and second durations are changed for subsequent cycles. Variations in the number of steps, types of steps, step durations, and the number of cycle repeats may be contemplated for the process cycle 650 and the example cited is not meant to be limiting.

The sensitizing solution may comprise an aqueous solution which includes an acid (e.g., hydrochloric (HCl), sulfuric (H₂SO4)) and a sensitizing agent such as tin chloride (SnCl₂), tin fluoride (SnF₂), platinum chloride (PtCl₂), or titanium chloride (TiCl₂), although other sensitizing agents may be used. The activating solution may comprise an aqueous solution which includes an acid (e.g., hydrochloric (HCl), sulfuric (H₂SO₄)) and an activating agent, such as palladium chloride (PdCl₂), for example, although other activating agents may be used. The sensitizing and activating agents may comprise metal salts or other chemical compounds which include catalytic materials (e.g., metals) which may initiate the electroless deposition of a metal. The catalytic materials may include but are not limited to palladium, tin, platinum, gold, rhodium, ruthenium, magnesium, osmium, iridium, iron, copper, cobalt, lead, mercury, nickel, aluminum, titanium, and carbon. In one embodiment, the nanofilament layer 504 is immersed in the sensitizing or activating solution for a duration of about 1 minute to about 30 minutes. In another embodiment, the nanofilament layer 504 is immersed in the sensitizing or activating solution for a duration of between about 15 seconds and about 60 seconds.

In another embodiment, the supplementary layer 503 is formed on the nanofilament layer 504 and the initiation-adhesion layer 506 is formed on the supplementary layer 503, and the embodiments described herein for step 606 may be applied to the supplementary layer 503 instead of the nanofilament layer 504 for forming the initiation-adhesion layer 506.

Referring to FIG. 6A, in a step 608, the metallic layer 508 is deposited on the initiation-adhesion layer 506 using one or more deposition techniques which include but are not limited to sputtering, chemical vapor deposition, plasma enhanced chemical vapor deposition, atomic layer deposition, metal-organic chemical vapor deposition, electrochemical deposition, electroless deposition, and electrophoresis. The step 608 may comprise multiple steps for depositing multiple metal layers which form the metallic layer 508, and each metal layer may be deposited using a different deposition technique.

In one embodiment, the metallic layer 508 is deposited using electroless deposition. The initiation-adhesion layer 506 is formed in the step 606 to provide a suitable catalytic material which can initiate an electroless plating process. The initiation-adhesion layer 506 is then immersed into one or more electroless plating solutions containing metal ions which are reduced to the metallic state to form the metallic layer 508. The initiation-adhesion layer 506 may be immersed sequentially into a series of electroless plating solutions to deposit one or more metal layers which form the metallic layer 508. The thickness “t4” of the metallic layer 508 depends in part on the duration of immersion of the initiation-adhesion layer 506 in each of the one or more plating solutions, and the thickness of each metal layer increases with a longer immersion time. The electroless plating solutions may also be heated to increase the deposition rate. In one embodiment, the electroless plating solutions are heated to temperatures ranging from about 18° C. to about 95° C. In one embodiment, the initiation-adhesion layer 506 is immersed in an electroless plating solution for a period ranging from about 30 seconds to about 60 minutes. In another embodiment, the initiation-adhesion layer 506 is immersed in an electroless plating solution for a period ranging from about 60 seconds to about 3 minute

In another embodiment, the metallic layer 508 is deposited using electrochemical deposition and the initiation-adhesion layer 506 comprises an electrically conductive nucleation or seed layer which enables the electrochemical plating of a metal thereon. The initiation-adhesion layer 506 is immersed into a plating solution which comprises an electrolyte bath in which is disposed an electrode (e.g., anode) comprising the metal to be plated, or metal such as platinum coated titanium. The initiation-adhesion layer 506 functions as a counter-electrode (e.g., cathode) and the electrodes are suitably connected to a power supply which provides a plating current for depositing metal onto the initiation-adhesion layer 506. The plating current may be a direct current (DC) or a pulsed plating waveform delivered by the power supply. The initiation-adhesion layer 506 may be immersed into a series of electrolyte solutions to deposit multiple metal layers which form the metallic layer 508. The electrolyte solution typically comprises an aqueous bath which includes a metal salt containing the metal to be plated, an acid (or base), and additives. The additives (e.g., levelers, brighteners, surfactants) may be added to improve the quality and conformality of the deposited metal layer.

Each of the steps 606 and 608 may also comprise the deposition of one or more supplementary materials described herein which may enhance or modify properties of the nanofilament composite material 500, and such materials may include diamond, diamond-like carbon (DLC), fluorinated carbon, silicates, metal oxides, metal fluorides, ceramics, or polymers, or other materials. The properties of the nanofilament composite material 500 which may be enhanced or modified include but are not limited to flexural rigidity, thermal and/or electrical conductivity, coefficient of thermal expansion, wear resistance, and other properties. Diamond or DLC, for example, may be deposited onto a flexible host substrate 300 (e.g., fiber, sheet) to improve the flexural rigidity of the host substrate 300.

The supplementary materials may be deposited using the deposition techniques described herein for forming the supplementary layer 503 in the step 601. The supplementary materials may also be co-deposited with other materials which are used to form the initiation-adhesion layer 506 and the metallic layer 508. For example, the supplementary materials may be co-deposited with sensitizing agents, activating agents, seed layers, nucleation layers, initiating layers, and/or metal plating layers. The supplementary materials may also be deposited before or after each of the steps 606 and 608. In one embodiment, a supplementary material is deposited using more than one deposition technique, such as electrophoresis followed by electrochemical plating, for example.

Methods for depositing supplementary materials (e.g., diamond, DLC, fluorinated carbon) using wet deposition processes such as electrochemical deposition, electroless deposition, or electrophoresis are disclosed in U.S. Pat. Nos. 3,753,667, 5,836,796, and 6,156,390. A powder comprising particles of supplementary material may be prepared and added to one or more solutions which are used in the wet deposition process. The solutions to which the powder may be added include but are not limited to electroless plating solutions, electrochemical plating solutions, pre-treatment solutions, sensitizing solutions, activating solutions, and electrophoresis solutions. The size of the particles in the powder may be controlled so that the solution forms a stable suspension or colloidal solution which facilitates the deposition of the supplementary material. In one embodiment, the size of the particles of the supplementary material is controlled to have an average diameter of less than a few tens of nanometers, although other particle sizes (e.g., sub-micrometer, micrometer) may be used depending upon the material, deposition solution, and deposition technique used. For example, the size of diamond or DLC particles may be controlled to have an average diameter of less than about 10 nanometers.

The particles of supplementary material may be co-deposited with a metal onto a plating surface during a wet deposition process, such as electrochemical or electroless deposition, for example. The metal particles in the electroless or electrochemical solution may entrain the particles of supplementary material during the deposition process so that both the metal and supplementary material are co-deposited onto the plating surface. Alternately, the wet deposition process (e.g., electrophoresis) may deposit only the supplementary material onto a surface without co-depositing other materials. In one embodiment, a supplementary material is co-deposited with a metal in an electroless or electrochemical plating solution in the step 606. In another embodiment, a supplementary material is co-deposited with a metal in an electroless or electrochemical plating solution in the step 608. In one embodiment, the supplementary material comprises diamond or DLC.

Referring to FIG. 6A, an optional anneal step may be performed in a step 610 to stabilize or enhance the properties of one or more materials within the nanofilament composite material 500. For example, the metallic layer 508 may be annealed to reduce the internal stresses within the metal and increase the metallic grain size to increase the conductivity of the metal. Annealing may also reduce some instabilities in the properties of the metallic layer 508. For example, the electrochemical deposition of copper can result in a self-annealing behavior of the copper following deposition. The self-annealing of the copper can occur at room temperature and can cause a gradual decrease in sheet resistance and hardness of the copper film. Annealing can decrease the time required to reach stable values for the sheet resistance and hardness of the copper layer.

Various parameters may be used for the annealing process in step 610. In one embodiment, the annealing temperature may range from about 75° C. to about 450° C. In one embodiment, the annealing time may range from about 1 minute to about 120 minutes. The annealing may be performed under vacuum or at atmospheric pressures or above, and may be conducted in environments containing inert gases (e.g., nitrogen, hydrogen, argon, helium) which prevent oxidation of the nanofilament composite material 500. In one embodiment, the anneal process is performed in an oxygen containing environment so that an oxide layer can be formed on the exposed surfaces. The formed oxide layer(s) can be useful, since it may act as an active material layer in a formed lithium ion battery. The annealing process may also be conducted in an environment containing one or more gases which form a plasma.

The method steps 600 shown in FIG. 6A and described herein may also include additional cleaning and rinsing steps which may occur before, during, or after each of the steps 601, 602, 604, 606, 608, and 610. Also, any solutions which are used for processing may be heated and/or agitated to facilitate deposition, cleaning, rinsing, or other processing. The solutions may be agitated mechanically, ultrasonically, or by other means.

The formation process shown in FIG. 6A and described herein may be implemented using various types and combinations of processing apparatuses. The choice of apparatuses used may depend, in part, upon the type of host substrate used in the nanofilament composite material 500.

Nanofilament Composite Material Formation Apparatus

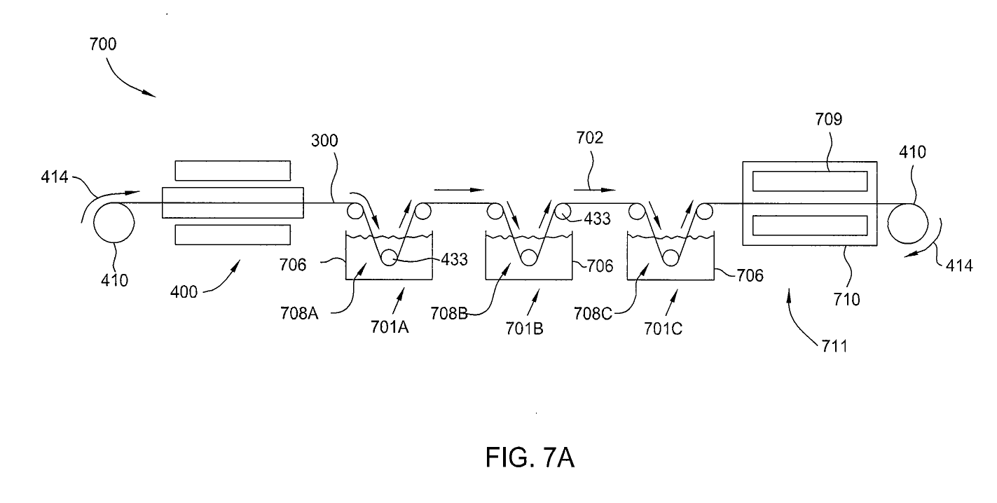

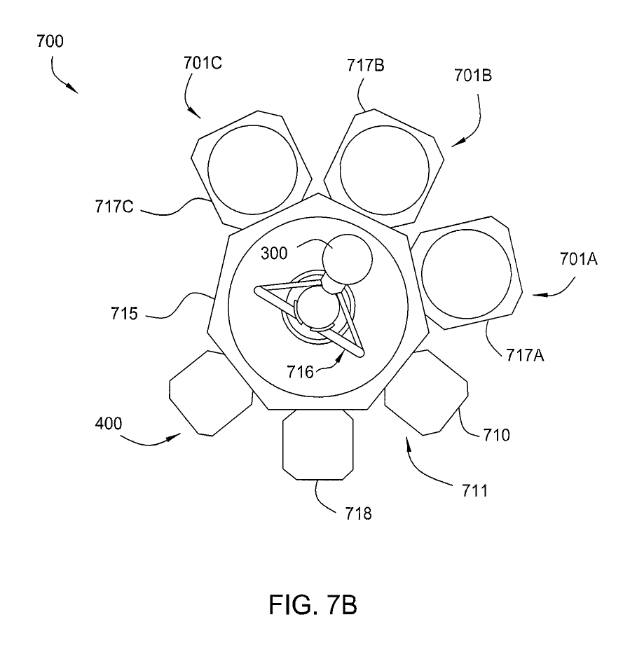

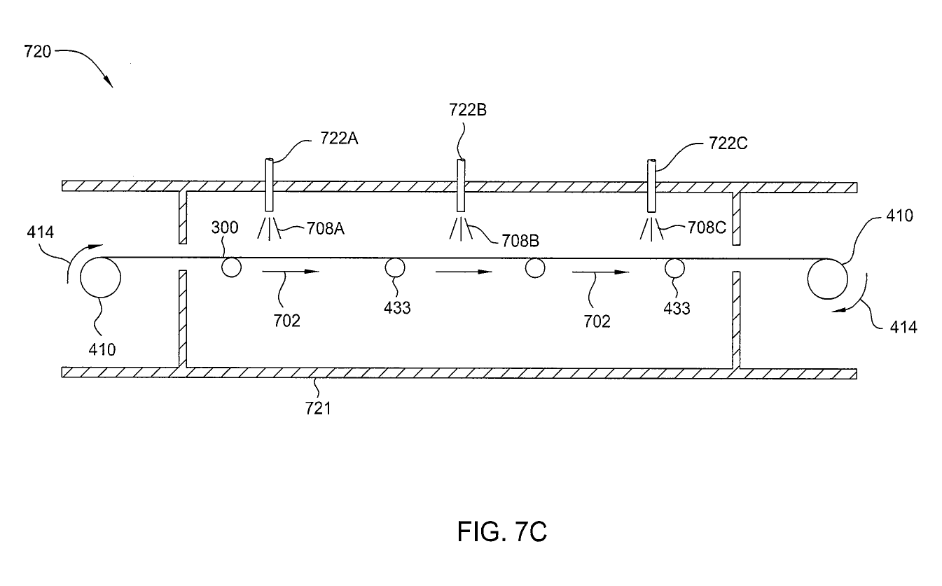

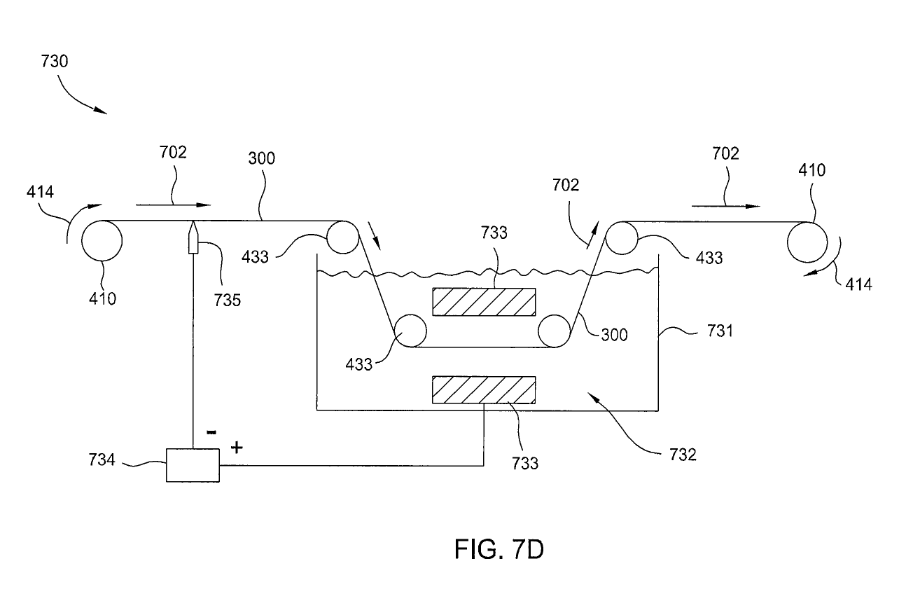

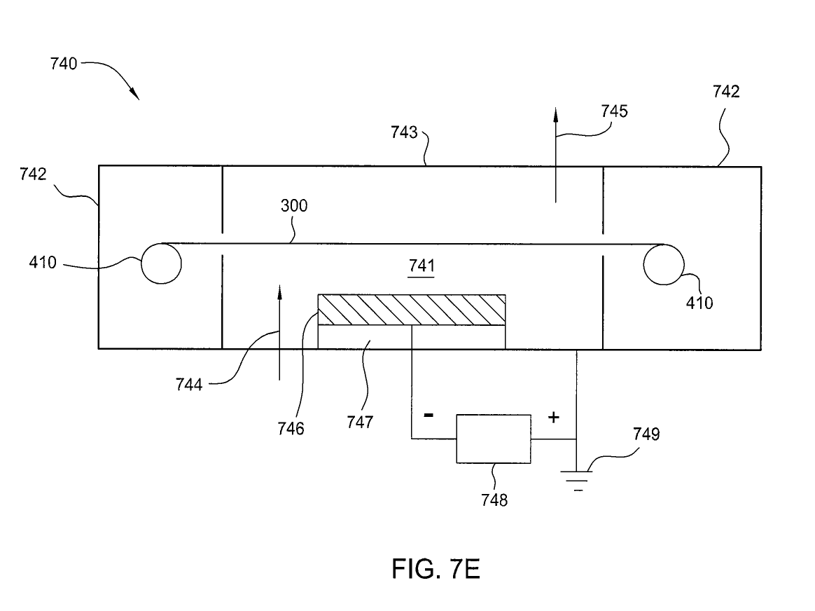

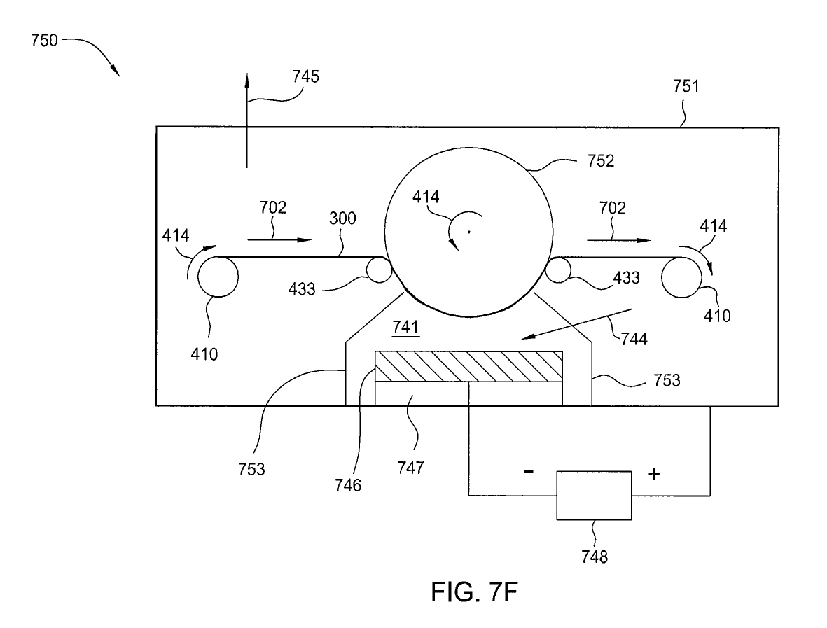

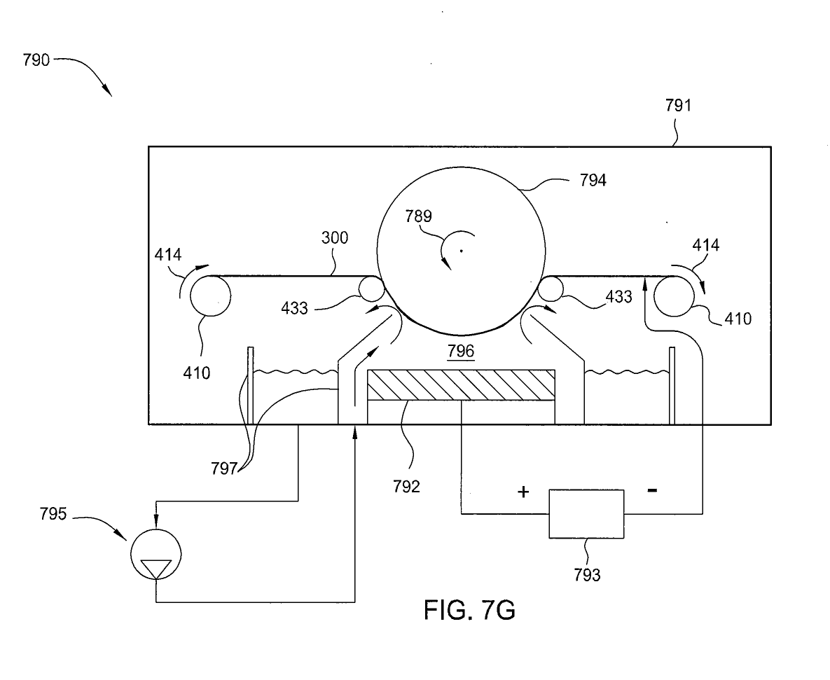

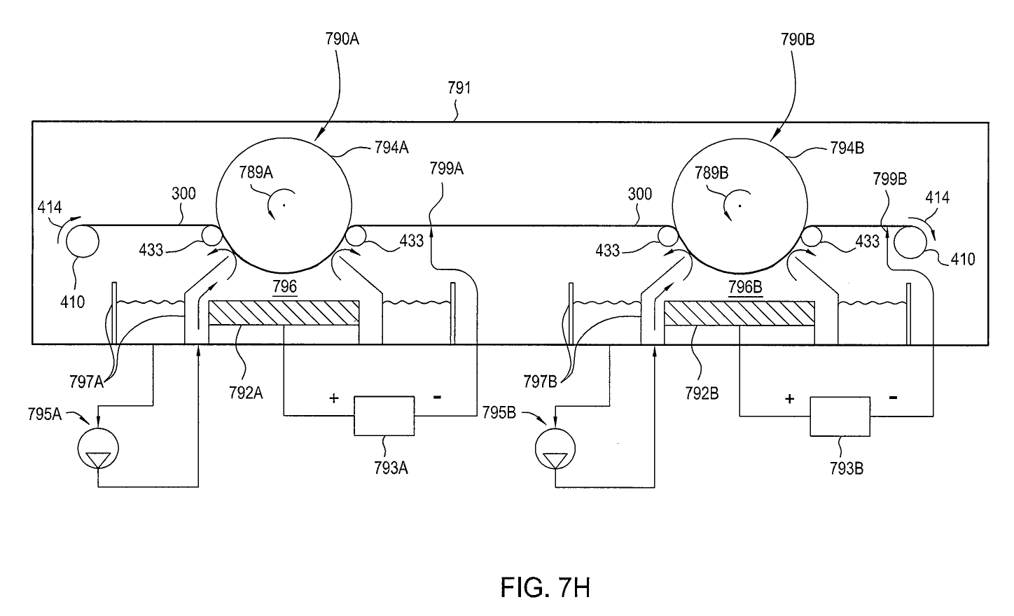

FIG. 7A is a simplified schematic view of an apparatus for forming the nanofilament composite material shown in FIGS. 5A-5B according to one embodiment described herein. A processing apparatus 700 comprises primary supports 410 and secondary supports 433 for moving a continuous host substrate 300, such as a fiber, sheet, or web, for example, through the processing apparatus 700. The direction of motion of the host substrate 300 is indicated by the motion direction 702. The processing apparatus 700 includes a nanofilament growth apparatus 400, processing stations 701A-C, and an annealing station 711. Although only three processing stations 701A-C are shown, the processing apparatus 700 may have any number of stations for processing. In one embodiment, the apparatus 700 comprises the one or more processing stations are disposed along a direction to sequentially process the host substrate in a linear or “in-line” type fashion.

The processing stations 701A-C are adapted to contain processing gases or liquids. In one embodiment, the processing stations 701A-C are adapted to contain processing liquids 708A-C, respectively, and the liquids are contained within processing tanks 706. Each processing tank 706 comprises any suitable container for containing the required amount and type of liquid needed for processing. The processing stations 701A-C are adapted to perform various types of processing which include but are not limited to depositing metals, depositing supplementary materials, activating, sensitizing, rinsing, cleaning, and intercalating graphitic nanofilaments. The processing liquids 708A-C may comprise electroless plating solutions, electrochemical plating solutions, sensitizing solutions, activating solutions, electrophoresis solutions, intercalation solutions, supplementary material solutions, pre-treatment solutions, rinsing solutions, cleaning solutions, or other types of solutions and combinations thereof for processing the host substrate 300.

In one embodiment, the processing apparatus 700 is adapted for electroless deposition. The sequential processing of a continuous host substrate 300 is described herein for a representative portion of the continuous substrate which moves from one station to the next for processing. The host substrate 300 first moves through the nanofilament growth apparatus 400 to form graphitic nanofilaments on the host substrate 300. In one embodiment, the nanofilament growth apparatus 400 comprises a tube furnace. Next, the host substrate 300 moves to the processing station 701A and passes through the processing liquid 708A which comprises a sensitizing solution. The host substrate 300 then moves to the processing station 701B and passes through the processing liquid 708B which comprises an activating solution. The processing liquids 708A-B form the initiation-adhesion layer 506 on the host substrate 300. Next, the host substrate 300 moves to the processing station 701C which contains the processing liquid 708C which comprises an electroless plating solution which deposits metal over the initiation-adhesion layer 506 to form the metallic layer 508. In another embodiment, one or more of the processing stations 701A-C may be adapted for electrochemical plating (see FIG. 7D).

It is to be understood that the processing apparatus 700 may comprise additional stations and solutions for processing to enable various processing sequences, such as the sequence shown in FIG. 6B and described herein. For example, the host substrate 300 may pass through a cleaning solution before reaching the processing station 701A and then may pass through rinsing solutions after each of the processing stations 701A-C.

Finally, the host substrate 300 moves to an annealing station 711 which comprises one or more heating elements 709 (e.g., resistive heaters, lamps) for annealing the nanofilament composite material 500. The annealing station 711 may also include an annealing chamber 710 which allows the annealing to be performed under controlled pressures (e.g., vacuum) and within controlled gas environments (e.g., inert gases).

The processing apparatus 700 shown in FIG. 7A and described herein may be suitably adapted for both wet and dry processing of the host substrate 300 which comprises a continuous substrate. The wet and dry processing techniques include but are not limited to the deposition techniques described herein. In one embodiment, one or more of the processing stations 701A-C are replaced with stations adapted for dry processing of a continuous substrate.

FIG. 7B is a simplified schematic view of another embodiment described herein for the apparatus shown in FIG. 7A. The host substrate 300 comprises a discrete substrate, such as a wafer, panel or short fiber, for example. The processing apparatus 700 comprises a cluster tool which includes a mounting platform 715, a primary support 716 which comprises a robot, the processing stations 701A-C, the annealing station 711, and the nanofilament growth apparatus 400. The nanofilament growth apparatus 400 may comprise a chamber (see FIG. 4E, for example).

The processing stations 701A-C comprise process chambers 717A-C, respectively, and the process chambers 717A-C are adapted to perform the desired processing at their respective processing stations 701A-C. The processing stations 701A-C are adapted to perform various types of processing which are described herein for forming the nanofilament composite material 500. The processing apparatus 700 may be adapted to have any number of stations and chambers for processing the host substrate 300. The annealing station 711 comprises the annealing chamber 710.

The process chambers 717A-C, annealing chamber 710, and nanofilament growth apparatus 400 are suitably mounted to the mounting platform 715 so that the primary support 716 (i.e., robot) can transfer the host substrate 300 between the chambers and the nanofilament growth apparatus 400, and the host substrate 300 may be transferred between the chambers in a pre-determined sequence in order to form the nanofilament composite material 500. The robot may also be adapted to hold, position, and release the host substrate 300 at various steps in the substrate transfer and load/unload sequence. The robot may include a wafer blade or other fixture which allows one or more discrete host substrates 300 (e.g., wafers, short fibers, etc.) to be transferred between chambers and placed into, positioned within, and removed from a chamber.

The processing of the host substrate 300 may be performed under vacuum or at atmospheric pressure. In one embodiment, the mounting platform 715 comprises a vacuum chamber (e.g., transfer or buffer chamber) which is adapted to allow the robot to transfer the host substrate 300 under vacuum to each of the chambers. In addition to processing chambers, the processing apparatus 700 may include other types of chambers to facilitate substrate processing, transfer or handling. For example, the processing apparatus 700 may include a loadlock chamber 718 which stores un-processed and/or processed host substrates 300.

FIG. 7C is a simplified schematic view of an apparatus for depositing materials onto graphitic nanofilaments formed on the host substrate 300 according to one embodiment described herein. A processing station 720 comprises a tank 721 and primary supports 410 and secondary supports 433. The primary supports 410 and secondary supports 433 are adapted for supporting and moving a continuous (e.g., fiber, sheet, web) or discrete (e.g., panel) host substrate 300 in the motion direction 702. The processing station 720 also comprises dispensing nozzles 722A-C for dispensing processing liquids 708A-C, respectively. Although only three dispensing nozzles 722A-C are shown, the processing station 720 may have any number of nozzles for dispensing any number of liquids for substrate processing.

The processing liquids 708A-C may comprise any of the processing solutions described herein for processing the host substrate 300. In one embodiment, the processing liquids 708A-C comprise a sensitizing solution, an activating solution, and an electroless plating solution, respectively. Additional nozzles for dispensing cleaning, rinsing, or other processing solutions may be disposed before or after each of the dispensing nozzles 722A-C. The processing station 720 may be suitably adapted to control the flow and distribution of the processing liquids 708A-C on the surface of the host substrate 300 to provide the desired deposition thereon.

FIG. 7D is a simplified schematic view of an apparatus for depositing materials onto graphitic nanofilaments formed on the host substrate 300 according to another embodiment described herein. A processing station 730 adapted for electrochemical plating comprises a tank 731 filled with an electrolyte plating solution 732. One or more anodes 733 are disposed in the electrolyte plating solution 732. The one or more anodes 733 comprise a desired plating metal and each anode 733 is suitably shaped and disposed about the host substrate 300 to facilitate depositing metal onto one or more surfaces of the host substrate 300.

The host substrate 300 comprises a continuous substrate, such as a fiber, sheet, or web, for example. The processing station 730 also comprises primary supports 410 and one or more secondary supports 433 which position and guide the host substrate 300 as it moves through the electrolyte plating solution 732 near the one or more anodes 733. The secondary supports 433 may comprise a suitable material (e.g., electrically non-conducting) to prevent plating onto the secondary supports 433 which are exposed to the electrolyte plating solution 732.

One or more surfaces of the host substrate 300 comprise plating surfaces which are electrically conductive. Each plating surface may comprise a metal seed layer which is deposited onto the host substrate 300 before electrochemical plating. The processing station 730 further comprises a power supply 734 (e.g., direct current) and a contact brush 735 or other suitable means which provides electrical contact with the one or more plating surfaces of the host substrate 300 as it moves in the motion direction 702. The power supply 734 is connected with the polarity shown to the one or more anodes 733 and the one or more conductive plating surfaces (i.e., cathodes) of the host substrate 300. The power supply 734 provides a plating current which deposits metal onto the plating surfaces of the host substrate 300 as it moves through the electrolyte plating solution 732.

In another embodiment, the processing station 730 is adapted for the electrophoretic deposition of metals or supplementary materials. The electrolyte plating solution 732 is replaced with an electrophoresis solution which contains the desired metal or supplementary material to be deposited. The one or more anodes 733 may be replaced with counter-electrodes so that material may be deposited on the primary electrode which comprises the plating surfaces of the host substrate 300. Alternately, an electrically conductive tank 731 may function as the counter electrode. The power supply 734 polarity as shown in FIG. 7D may be used for cathodic electrophoresis. The polarity may be reversed for anodic electrophoresis.

FIG. 7E is a simplified schematic view of an apparatus for depositing materials onto graphitic nanofilaments formed on the host substrate 300 according to one embodiment described herein. A processing station 740 for sputter depositing various materials onto a host substrate 300 comprises a process chamber 743 and buffer chambers 742. The buffer chambers 742 contain primary supports 410 for supporting and moving a continuous or discrete host substrate 300 through a processing region 741. One or more of the buffer chambers 742 may be suitably adapted to allow transfer of the host substrate 300 from the buffer chamber 742 to another chamber or station in the processing apparatus 700.

The process chamber 743 and buffer chambers 742 may be coupled to and in fluid communication with a vacuum pumping system (not shown) to remove exhaust gases 745 and allow adjustment of the pressure in the process chamber 743 and in the buffer chambers 742. The process chamber 743 may operate at vacuum or near-atmospheric pressures, and the buffer chambers 742 may operate at pressures higher than the pressure in the process chamber 743.

The process chamber 743 also includes a target 746 coupled to an insulative source block 747 which may comprise a magnetron and a heat exchanger or other cooling means. The target 746 is electrically isolated from the process chamber 743 and is electrically connected to a power supply 748. The other terminal of the power supply 748 may be connected to the process chamber 743 and a ground 749 with the polarity shown. The power supply 748 is a DC power supply (as shown) which may be used to sputter electrically conductive materials. In another embodiment, the power supply 748 is an alternating power supply (e.g., radio frequency generator) which may be used to sputter electrically insulative materials. In another embodiment, the power supply 748 is connected to the target 746 and another suitable counter-electrode within the process chamber 743.

The target 746 comprises a desired deposition material, such as a metal or metal alloy, for example. A process gas 744 is introduced into the process chamber 743 and a plasma is formed in the processing region 741. Material is sputtered from the target 746 and deposited onto the host substrate 300. The host substrate 300 may move during sputter deposition so that material is deposited along the length of the host substrate 300. The processing station 740 may be suitably adapted so that material may be deposited onto one or more sides of the host substrate 300. For example, the host substrate 300 may be rotated during deposition, or more than one target 746 may be disposed about the host substrate 300, or one target 746 may move about the host substrate 300. The processing station 740 may also be adapted for reactive sputtering.

FIG. 7F is a simplified schematic view of an apparatus for depositing materials onto graphitic nanofilaments formed on the host substrate 300 according to another embodiment described herein. A processing station 750 is adapted to sputter deposit material onto one side of a continuous host substrate 300 which comprises a tape, sheet, web or other flexible flat surface. The processing station 750 comprises a process chamber 751, target 746, source block 747, power supply 748, and a rotating chill drum 752 which rotates in the rotation direction 414. The rotating chill drum 752 functions as a support surface and cooling surface for the host substrate 300 as it moves over the target 746 in the motion direction 702. The processing station 750 also comprises primary supports 410 and secondary supports 433 to keep the host substrate 300 pressed against the chill drum 752 and enable movement of the host substrate 300 during the deposition process.

FIG. 7G is a simplified schematic view of a processing station 790 used to electrochemically deposit materials onto the portions of the host substrate 300. In one embodiment, the processing station 790 is used to electrochemically deposit materials onto the graphitic nanofilaments formed on the host substrate 300. The processing station 790 is adapted to electrochemically deposit a metal material onto a continuous host substrate 300 which comprises a tape, sheet, metal foil, polymeric material and metal foil, web or other flexible flat surface. The processing station 790 comprises an enclosure 791, anode 792, power supply 793, electrolyte tank 797, electrolyte pumping system 795 and a rotating drum 794 which rotates in the rotation direction 789. The rotating drum 794 functions as a support surface for the host substrate 300 as it moves through the processing region 796 of the electrolyte tank 797 that is filled with a flowing electrolyte material. During processing the power supply 793 cathodically biases the surface of the host substrate 300 relative to the anode 792 so that metal ion in the electrolyte will deposit on the surface of the host material 300. In one embodiment, the cathodic lead of the power supply 793 is in intimate electrical contact with portions of the host substrate 300, or layers formed thereon, by use of brush 799, or by biasing a conductive surface formed on part of the rotating drum 794. In one embodiment, the electrolyte solution comprises an aqueous bath which includes a metal salt containing the metal that is to be plated, an acid (or base), and additives. The processing station 790 may also comprise primary supports 410 and secondary supports 433 to keep the host substrate 300 pressed against the drum 794 and enable movement of the host substrate 300 during the deposition process.

In one embodiment, as illustrated in FIG. 7H, two or more metal layers may be serially formed on the host substrate 300 in two or more serially linked processing station, for example, in processing stations 790A and 790B. In each of the processing stations 790A, 790B a different electrolyte may be used to deposit different materials, or form layers of the same material having different chemical or physical properties. As shown in FIG. 7H, each of the processing station 790A and 790B are similarly configured as processing chamber 790 discussed above in relation to FIG. 7G.

The processing station 750 further comprises one or more shields 753 which enclose the processing region 741. The one or more shields 753 are adapted to confine sputtered material within the processing region 741 and allow process gases 744 to enter the processing region 741. The process chamber 751 may be coupled to and in fluid communication with a vacuum system (not shown) which is adapted to remove exhaust gases 745 and allow adjustment of the pressure in the process chamber 751. The power supply 748 is connected to the target 746 and a suitable counter-electrode (e.g., process chamber 751 or chill drum 752) to enable the formation of a plasma in the processing region 741.

The apparatuses described herein for nanofilament growth and the deposition of metals and other materials onto graphitic nanofilaments are not meant to be limiting, and other types of apparatuses may be contemplated for the formation of the nanofilament composite material 500. Further, various embodiments of the apparatuses described herein may be combined to form alternate apparatuses which may be used to form the nanofilament composite material 500. For example, the apparatuses shown if FIGS. 7C-7F and described herein may be adapted for use in the processing apparatus 700 shown in FIG. 7A. Additionally, the CVD apparatuses shown if FIGS. 4A-4E and described herein for nanofilament growth may be suitably adapted for depositing metals, supplementary materials, or for other CVD processing which may used to form the nanofilament composite material 500.

The apparatuses described herein may also be used to form the nanofilament composite material 500 according to other embodiments for the process shown in FIG. 6A and described herein.

Additional Formation Methods

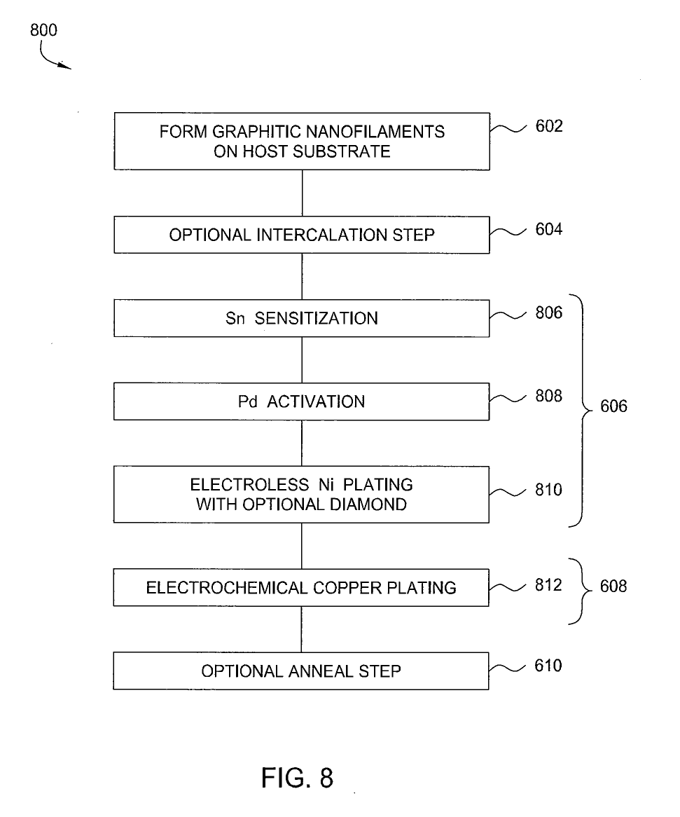

FIG. 8 illustrates one embodiment described herein for the formation process shown in FIG. 6A. The process comprises a series of method steps 800 which include electroless and electrochemical plating processes. The method steps 800 begin with the step 602 which comprises the formation of graphitic nanofilaments on the host substrate 300 to form the nanofilament layer 504 (see FIG. 5A). The graphitic nanofilaments are then intercalated with metal ions in the optional step 604. Methods which may be used to intercalate the graphitic nanofilaments are described herein for the step 604. Next, in a step 806, the nanofilament layer 504 is immersed in a sensitizing solution which includes tin (Sn). In one embodiment, the sensitizing solution is an aqueous solution which includes hydrochloric acid (HCl) and tin chloride (SnCl₂). In a step 808, an activation step, the nanofilament layer 504 is immersed in an activating solution which includes palladium (Pd). In one embodiment, the activating solution is an aqueous solution which includes hydrochloric acid (HCl) and palladium chloride (PdCl₂). In one embodiment, the nanofilament layer 504 is exposed to the sensitizing or activating solution for a period ranging between about 1 second to about 30 minutes. In another embodiment, the nanofilament layer 504 is exposed to the sensitizing or activating solution for a period ranging between about 15 seconds and about 60 seconds

In a step 810, nickel (Ni) is deposited onto the nanofilament layer 504 by immersing the layer in an electroless plating solution containing nickel. The nickel layer may function as a seed layer for subsequent metal deposition. In one embodiment, diamond or DLC is co-deposited with the nickel in step 810. Diamond or DLC particles may be added to the electroless Ni plating solution and then co-deposited with the nickel, as described herein. In another embodiment, diamond or DLC is co-deposited with a metallic material in either step 806, 808, or 812. The step 606 comprises the steps 806, 808, and 810 which form the initiation-adhesion layer 506. In another embodiment, a metal other than nickel, such as copper, for example, is deposited in the step 810.

The electroless nickel plating solution comprises an aqueous solution of a nickel ion source, a reducing agent, a complexing agent, and other additives. The nickel source may include but is not limited to nickel chloride, nickel sulfate, nickel acetate, nickel phosphate, nickel fluoroborate, derivatives thereof, hydrates thereof or combinations thereof. The electroless nickel plating solution may comprise various solution types which include but are not limited to alkaline nickel phosphorous, acid nickel phosphorous, alkaline nickel-borax, and acid nickel-boron. Chemical reducing agents which may be used include but are not limited to sodium hypophosphite, sodium hypophosphate, sodium borohydride, N-dimethylamine borane (DMAB), N-diethylamine borane (DEAB), hydrazine, and combinations thereof. In one embodiment, the electroless nickel plating solution is maintained at a temperature which ranges from about 20° C. to about 90° C. In one embodiment, the nanofilament layer 504 is exposed to the electroless nickel plating solution for a duration between about 1 minute to about 10 minutes.

In a step 812, a layer of copper (Cu) is electrochemically deposited onto the nickel layer formed in step 810. The copper is deposited by immersing the nickel layer in an electrolyte solution containing copper and then providing a plating current. The step 608 comprises the step 812 which forms the metallic layer 508. Finally, in the optional step 610, the nanofilament composite material 500 is annealed.

The electrolyte solution comprises an aqueous solution containing a copper ion source and one or more acids. The electrolyte solution may also contain one or more additives, such as an accelerator, a suppressor, a leveler, a surfactant, a brightener, or combinations thereof to help control the stress, grain size and uniformity of the electrochemically deposited copper layer(s). Useful copper ion sources include copper sulfate (CuSO₄), copper chloride (CuCl₂), copper acetate (Cu(CO2CH₃)₂), copper pyrophosphate (Cu₂P₂O₇), copper fluoroborate (Cu(BF₄)₂), derivatives thereof, hydrates thereof or combinations thereof. The electrolyte solution may also be based on alkaline copper plating baths (e.g., cyanide, glycerin, ammonia, etc.). In one embodiment, the temperature of the electrolyte solution is controlled to within about 18° C. to about 85° C. to maximize the plating rate. In another embodiment, the temperature of the electrolyte solution is controlled to within about 30° C. to about 70° C. In another embodiment, the temperature of the electrolyte solution is controlled to within about 18° C. to about 24° C.

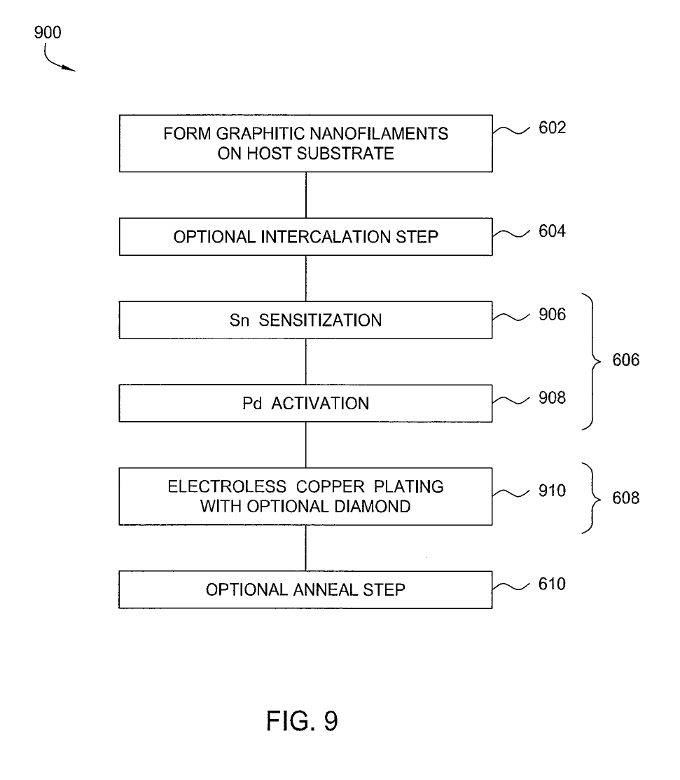

FIG. 9 illustrates another embodiment described herein for the formation process shown in FIG. 6A. A series of method steps 900 includes an electroless plating process. The method steps 900 start with the step 602 which forms the nanofilament layer 504 which may be intercalated with metal ions in the optional step 604. Next, in a step 906, the nanofilament layer 504 undergoes sensitization by immersing the layer in a sensitizing solution which includes tin (Sn). Following sensitization, the nanofilament layer 504 is immersed, in a step 908, in an activating solution which includes palladium (Pd). The step 606 comprises the steps 906 and 908 which form the initiation-adhesion layer 506.

In a step 910, copper is electrolessly deposited onto the initiation-adhesion layer 506 by immersing the layer is an electroless copper plating solution. The step 608 comprises the step 910 which forms the metallic layer 508. In one embodiment, diamond or DLC is co-deposited with the copper in the step 910. After the step 910, in the optional step 610, the nanofilament composite material 500 is annealed.

The electroless copper plating solution comprises an aqueous solution of a copper ion source, a reducing agent, a complexing agent, and other additives. Copper ion sources which may be used include but are not limited to copper chloride, copper sulfate, copper nitrate, copper formate, copper acetate, copper cyanide, derivatives thereof, hydrates thereof or combinations thereof. Chemical reducing agents which may be used include but are not limited to sodium hypophosphite, sodium hypophosphate, sodium borohydride, potassium borohydride, formaldehyde, paraformaldehyde, glyoxylic acid, hydrazine, formalin, polysaccharide, derivatives thereof or combinations thereof. In one embodiment, the electroless copper plating solution is maintained at a temperature which ranges from about 20° C. to about 90° C., and preferably between about 25° C. to about 60° C. In another embodiment, the electroless copper plating solution is maintained at a temperature which ranges from about 70° C. and about 85° C. In one embodiment, the nanofilament layer 504 is immersed in the electroless copper plating solution for a duration between about 1 minutes to about 60 minutes. In another embodiment, the nanofilament layer 504 is immersed in the electroless copper plating solution for a duration between about 1 and 5 minutes.

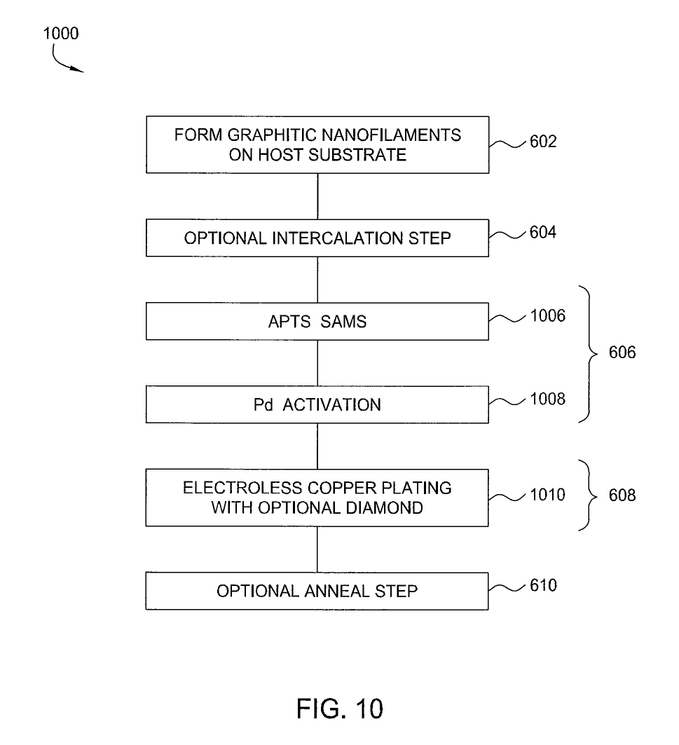

FIG. 10 illustrates one embodiment described herein for the formation process shown in FIG. 6A. The method steps 1000 include a modified electroless deposition process which does not use a sensitization step and which may provide improved adhesion of the plating metal to the nanofilament layer 504. In the steps 602 and 604, the nanofilament layer 504 is formed on the host substrate 300 and the graphitic nanofilaments may then be intercalated, if desired. Next, in a step 1006, the nanofilament layer 504 is exposed to a solution comprising the silanization reagent aminopropyltriethoxysilane (APTS) and a thin film of self-assembled monolayers (SAMs) of APTS is formed on the nanofilament layer 504. In a step 1008, the APTS film is exposed to an activating solution containing palladium chloride (PdCl₂) whereby palladium is deposited on the APTS film. In another embodiment, the palladium in the activating solution is replaced with another catalytic material which is deposited on the APTS film and which may initiate the electroless deposition of a metal. The step 606 comprises the steps 1006 and 1008 which form the initiation-adhesion layer 506.

Next, in a step 1010, copper is deposited on the initiation-adhesion layer 506 by immersing the layer in an electroless copper plating solution. In one embodiment, diamond or DLC is co-deposited with the copper in step 1010. The step 608 comprises the step 1010 which forms the metallic layer 508. Finally, in the optional step 610, the nanofilament composite material 500 is annealed. The material layers are rinsed in water (e.g., de-ionized water) after each of the steps 1006, 1008, and 1010. Methods for electroless metal plating using APTS self-assembled monolayers are reported by Xu et al., in “A New Activation Method for Electroless Metal Plating: Palladium Laden via Bonding with Self-Assembly Monolayers,” Chinese Chemical Letters, Vol. 13, No. 7, pp. 687-688, 2002.

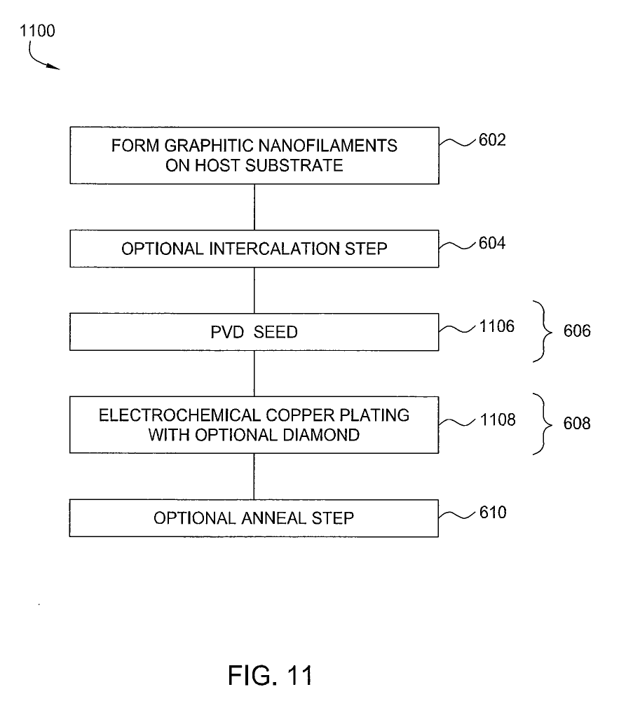

FIG. 11 illustrates another embodiment described herein for the formation process shown in FIG. 6A. The process comprises method steps 1100 which include a dry deposition process for the formation of the initiation-adhesion layer 506. After the optional intercalation step 604, a step 1106 forms a nucleation or seed layer onto the nanofilament layer 504. The seed layer is deposited using a physical vapor deposition (PVD) technique, such as sputtering or thermal evaporation, for example, although other PVD techniques may also be used. In one embodiment, the PVD seed layer is deposited using sputter deposition. The PVD seed layer comprises materials which include but are not limited to copper, lithium, tin, aluminum, bismuth, antimony, nickel, titanium, vanadium, chromium, manganese, iron, cobalt, silver, gold, zinc, and alloys thereof. In one embodiment, the PVD seed layer comprises copper. The step 606 comprises the step 1106 which forms the initiation-adhesion layer 506. Next, in a step 1108, copper is electrochemically deposited onto the PVD seed layer. In one embodiment, diamond or DLC is co-deposited with the copper in step 1108. The step 608 comprises the step 1108 which forms the metallic layer 508 which may be annealed in step 610.

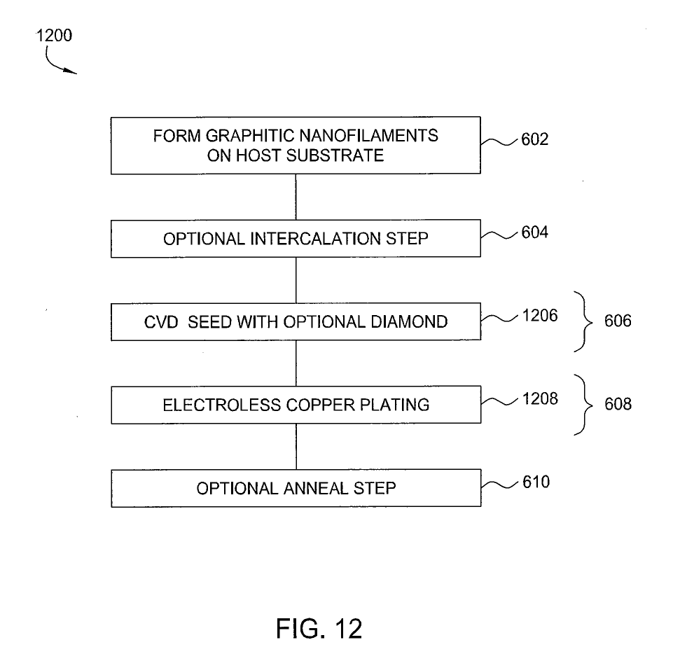

FIG. 12 illustrates one embodiment described herein for the formation process shown in FIG. 6A. The method steps 1200 begin with the step 602 to form the nanofilament layer 504, and this step is followed by the optional intercalation step 604. In a step 1206, a seed layer is deposited onto the nanofilament layer 504 using chemical vapor deposition (CVD). In one embodiment, the CVD seed layer comprises copper. Materials which may be used for the CVD seed layer include but are not limited to copper, lithium, tin, aluminum, bismuth, antimony, nickel, titanium, vanadium, chromium, manganese, iron, cobalt, silver, gold, zinc, and alloys thereof. In one embodiment, diamond or DLC is co-deposited with the seed material in step 1206. The diamond or DLC may be deposited using any suitable CVD methods known in the art for depositing diamond or DLC. In another embodiment, diamond or DLC is deposited before the seed material. The step 606 comprises the step 1206 which forms the initiation-adhesion layer 506. Next, in a step 1208, copper is deposited onto the CVD seed layer using electroless deposition. The step 608 comprises the step 1208 which forms the metallic layer 508 which may be annealed in step 610. In one embodiment, diamond or DLC is co-deposited with copper in the step 1208.

The process methods shown in FIGS. 8-12 and described herein may include additional embodiments. The host substrate 300 and any material layers thereon may undergo additional treatments before and/or after each of the process steps. The treatments include but are not limited to cleaning, rinsing, drying, heating, and cooling. The treatments may be performed by exposing the host substrate 300 to solutions, plasmas, radiation, or other means for treating the substrate and any material layers thereon. Also, the diamond or DLC may be deposited in a two-step process wherein the diamond or DLC is co-deposited with a metal followed by depositing only the metal to form a two-layer seed layer or a two-layer metallic layer 508.

While the foregoing is directed to embodiments of the present invention, other and further embodiments of the invention may be devised without departing from the basic scope thereof, and the scope thereof is determined by the claims that follow.

1. A high surface area electrode configured for use in an electrochemical energy storage device, comprising:
a host substrate;
a nanofilament layer comprising graphitic nanofilaments formed on a surface of the host substrate;
an initiation-adhesion layer disposed over the nanofilament layer; and
a metallic layer disposed on the initiation-adhesion layer.

2. The electrode of claim 1, wherein the initiation adhesion layer and the metallic layer are porous to allow the passage of metal ions through each layer.

3. The electrode of claim 1, wherein the host substrate comprises a fiber or a foil that comprises a material selected from the group consisting of polyimide, Kapton, glass, copper (Cu), aluminum (Al), nickel (Ni), and stainless steel.

4. The electrode of claim 1, wherein the graphitic nanofilaments comprise carbon nanotubes.

5. The electrode of claim 1, wherein the initiation-adhesion layer comprises one or more materials selected from a group consisting of tin (Sn), palladium (Pd), nickel (Ni), copper (Cu), and aminopropyltriethoxysilane (APTS).

6. The electrode of claim 1, wherein the metallic layer comprises copper, tin, or combinations thereof.

7. The electrode of claim 4, wherein the nanofilament layer further comprises one or more alkali metals.

8. The electrode of claim 1, further comprising additional material layers formed over the metallic layer wherein the additional material layers form an electrochemical storage device.

9. A method of forming an electrode used in an electrochemical energy storage device, comprising:
forming a nanofilament layer comprising graphitic nanofilaments on a surface of a host substrate, wherein said layer is formed using chemical vapor deposition (CVD);
forming an initiation-adhesion layer over the nanofilament layer; and
depositing a metallic layer on the initiation-adhesion layer.

10. The method of claim 9, further comprising forming one or more nanofilament formation areas and one or more supplementary layers over the surface of the host substrate, wherein the one or more supplementary layers are disposed between the formation areas and inhibit or prevent the growth of graphitic nanofilaments outside the formation areas.

11. The method of claim 9, further comprising intercalating the graphitic nanofilaments with species of one or more alkali metals.

12. The method of claim 9, wherein forming the nanofilament layer comprises forming carbon nanotubes.

13. The method of claim 9, wherein forming the initiation-adhesion layer further comprises depositing one or more catalytic materials for initiating the electroless deposition of a metal.

14. The method of claim 13, wherein depositing one or more catalytic materials further comprises immersing the nanofilament layer in a sensitizing solution comprising tin (Sn), and immersing the nanofilament layer in an activating solution comprising palladium (Pd).

15. The method of claim 9, wherein forming the initiation-adhesion layer further comprises forming a film of self-assembled monolayers of aminopropyltriethoxysilane (APTS) on the nanofilament layer and depositing a catalytic material on said film.

16. The method of claim 15, wherein the catalytic material comprises palladium (Pd).

17. The method of claim 9, wherein the metallic layer is deposited using electroless deposition or electrochemical deposition.

18. The method of claim 9, further comprising co-depositing of diamond or diamond-like carbon particles with the metallic layer.

19. The method of claim 18, wherein the co-depositing further comprises contacting the host substrate with one or more liquid solutions selected from a group consisting of sensitizing solutions, activating solutions, electroless plating solutions, and electrochemical plating solutions.

20. An apparatus for forming an electrode, comprising:
a first primary support and a second primary support each coupled to a portion of a host substrate;
a nanofilament growth apparatus adapted for growing graphitic nanofilaments on a portion of the host substrate disposed between the first primary support and the second primary support;
one or more processing stations adapted for metallizing the graphitic nanofilaments formed on the host substrate; and
an actuator coupled to the first primary support to position a portion of the host substrate in the nanofilament growth apparatus and the one or more processing stations.

21. The apparatus of claim 20, further comprising an annealing station that is adapted to receive a portion of the host substrate positioned between the first primary support and the second primary support.

22. The apparatus of claim 20, wherein the first primary support and second primary support each comprise one selected from a group consisting of a roller, supply reel, and take-up reel, wherein each said support is adapted to move the host substrate through the apparatus.

23. The apparatus of claim 20, wherein at least one processing station is adapted for electroless deposition or electrochemical deposition.

24. The apparatus of claim 20, wherein the nanofilament growth apparatus comprises a tube furnace or a chemical vapor deposition (CVD) chamber.

25. The apparatus of claim 20, wherein the nanofilament growth apparatus and the one or more processing stations are disposed along a direction to sequentially process the host substrate.
